(19) United States
(12) Patent Application Publication
(10) Pub. No.: US 2025/0142906 A1
(43) Pub. Date: May 1, 2025

(54) SEMICONDUCTOR DEVICE

(71) Applicant: SAMSUNG ELECTRONICS CO., LTD., SUWON-SI (KR)

(72) Inventors: SUNGUK JANG, Suwon-si (KR); JINBUM KIM, Suwon-si (KR); ILYOUNG YOON, Suwon-si (KR)

(21) Appl. No.: 18/655,387

(22) Filed: May 6, 2024

(30) Foreign Application Priority Data
Oct. 27, 2023 (KR) 10-2023-0145500

(51) Int. Cl. H01L 29/08; H01L 29/06; H01L 29/423; H01L 29/66; H01L 29/775; H01L 29/786

(52) U.S. Cl. CPC H10D 62/151; H10D 30/014; H10D 30/031; H10D 30/43; H10D 30/6735; H10D 30/6757; H10D 62/121

(57) ABSTRACT

A semiconductor device includes a barrier rib separating the source/drain region into a plurality of parts. A first part of the plurality of parts of the source/drain region includes a first epitaxial layer having a lower end disposed on the active pattern and a sidewall part extending from the lower end in a third direction crossing first and second directions and connected to the channel pattern. A second epitaxial layer is disposed on the first epitaxial layer and has a composition different from a composition of the first epitaxial layer. In a cross-section cut from the center of the source/drain region in the first direction to the second and third directions, a lower end of the first epitaxial layer of the first part of the plurality of parts of the source/drain region has an asymmetric shape around an axis extending in the third direction.

### CROSS-REFERENCE TO RELATED APPLICATION

This application claims priority under 35 U.S.C. § 119 to Korean Patent Application No. 10-2023-0145500, filed on Oct. 27, 2023 in the Korean Intellectual Property Office, the disclosure of which is incorporated by reference in its entirety herein.

### 1. Technical Field

The present disclosure relates to a semiconductor device, for example, a transistor

including a nano wire or a nano sheet, or a fin-type transistor containing a channel pattern of a fin-type pattern shape.

### 2. Discussion of Related Art

A semiconductor is a material that is between a conductor and an insulator and refers to a material that conducts electricity under predetermined conditions. Using these semiconductor materials, various semiconductor devices may be manufactured, such as memory devices, etc. These semiconductor devices may be used in various electronic devices.

As the electronic products industry develops, consumer demands for characteristics of the semiconductor device are increasing. For example, demands for high reliability, higher speed and/or multi-functionality for the semiconductor devices are increasing. Therefore, structures within the semiconductor devices are becoming increasingly complex and integrated to provide these characteristics.

### SUMMARY

One aspect of the present disclosure is to provide a semiconductor device that may reduce defects caused by a heterogeneous interface with a barrier rib when growing an epitaxial layer in source/drain regions while reducing a strain loss through the barrier rib that separates the source/drain regions.

According to an embodiment of the present disclosure, a semiconductor device includes an active pattern extending in a first direction. A source/drain pattern is disposed on the active pattern. The source/drain pattern includes source/drain regions spaced apart from each other in the first direction. A channel pattern is disposed between the source/drain regions. A gate pattern extends in a second direction crossing the first direction. The gate pattern extends between the source/drain regions and surrounds at least a portion of the channel pattern. A barrier rib extends in the first direction. The barrier rib separates the source/drain region into a plurality of parts. A first part of the plurality of parts of the source/drain region includes a first epitaxial layer having a lower end disposed on the active pattern and a sidewall part extending from the lower end in a third direction crossing the first direction and the second direction. The sidewall part is connected to the channel pattern. A second epitaxial layer is disposed on the first epitaxial layer. The second epitaxial layer has a composition different from a composition of the first epitaxial layer. In a cross-section cut from a center of the source/drain region in the first direction to the second and third directions, a lower end of the first epitaxial layer of the first part of the plurality of parts of the source/drain region has an asymmetric shape around an axis extending in the third direction.

According to an embodiment of the present disclosure, a semiconductor device includes an active pattern extending in a first direction. A source/drain pattern is disposed on the active pattern. The source/drain pattern includes source/drain regions spaced apart from each other in the first direction. A channel pattern is disposed between the source/drain regions. A gate pattern extends in a second direction crossing the first direction. The gate pattern extends between the source/drain regions and surrounding the channel pattern. A barrier rib extends in the first direction. The barrier rib separates the source/drain region into a plurality of parts. A first part of the plurality of parts of the source/drain region includes a first epitaxial layer having a lower end disposed on the active pattern and a sidewall part extending from the lower end in a third direction crossing the first direction and the second direction. The sidewall part is connected to the channel pattern. A second epitaxial layer is disposed on the first epitaxial layer. The second epitaxial layer has a composition different from a composition of the first epitaxial layer. In a cross-section cut from a center of the source/drain region in the first direction to the second direction and the third direction, a thickness in the third direction of the lower end of the first epitaxial layer of the first part of the plurality of parts of the source/drain region has a minimum value at a first point positioned furthest from the barrier rib in the second direction, and a value greater than the minimum value at a second point in direct contact with the barrier rib.

According to an embodiment of the present disclosure, a semiconductor device includes an active pattern extending in a first direction. A source/drain pattern is disposed on the active pattern. The source/drain pattern includes source/drain regions spaced apart from each other in the first direction. A channel pattern is disposed between the source/drain regions. A gate pattern extends in a second direction crossing the first direction. The gate pattern extends between the source/drain regions and surrounds the channel pattern. A barrier rib extends in the first direction. The barrier rib separates the source/drain region into a plurality of parts. A first part of the plurality of parts of the source/drain region includes a first epitaxial layer having a lower end disposed on the active pattern and a sidewall part extending from the lower end in a third direction crossing the first direction and the second direction. The sidewall part is connected to the channel pattern. A second epitaxial layer is disposed on the first epitaxial layer. The second epitaxial layer has a composition different from a composition of the first epitaxial layer. In a cross-section cut from a center of the source/drain region in the first direction to the second and third directions, the lower end of the first epitaxial layer is in surface-contact with the barrier rib.

According to embodiments, the semiconductor device may reduce defects caused by heterogeneous interfaces with the barrier rib when growing the epitaxial layer of the source/drain region, while reducing a strain loss through the barrier rib that separates the source/drain region.

### BRIEF DESCRIPTION OF THE DRAWINGS

FIG. 1 is a top plan view showing a semiconductor device according to an embodiment.

FIG. 2 is a cross-sectional view cut along a line A-A′ in FIG. 1.

FIG. 3 is a cross-sectional view cut along a line B-B′ in FIG. 1.

FIG. 4 is a cross-sectional view cut along a line C-C′ in FIG. 1.

FIG. 5 is a cross-sectional view cut along a line D-D′ in FIG. 1.

FIG. 6 is an enlarged cross-sectional view of a region P in FIG. 5.

FIG. 7 is a cross-sectional view corresponding to FIG. 6. according to a comparative embodiment.

FIG. 8 is an enlarged cross-sectional view of a region S of FIG. 2.

FIG. 9 to FIG. 11 show a semiconductor device according to embodiments, and are cross-sectional views corresponding to FIG. 2, FIG. 5, and FIG. 6, respectively.

FIG. 12 to FIG. 16 show a semiconductor device according to embodiments, and are cross-sectional views corresponding to FIG. 1 to FIG. 5 respectively.

FIG. 17 to FIG. 96 are views of a method of manufacturing a semiconductor device according to some embodiments.

### DETAILED DESCRIPTION OF EMBODIMENTS

Hereinafter, with reference to the accompanying drawings, embodiments of the present disclosure will be described in detail. However, embodiments of the present disclosure may be embodied in many different forms and are not limited to the described embodiments set forth herein.

In addition, to clearly describe the present disclosure, parts unrelated to the descriptions are omitted, and the same or similar elements are denoted with the same reference numerals throughout the specification.

Further, since sizes and thicknesses of constituent members shown in the accompanying drawings may be arbitrarily given for better understanding and ease of description, embodiments of the present disclosure are not necessarily limited to the illustrated sizes and thicknesses. In the drawings, the thickness of layers, films, panels, regions, etc., may be exaggerated for clarity. In the drawings, for better understanding and ease of description, thicknesses of some layers and areas are excessively displayed.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, in the specification, the word “on” or “above” means positioned on or below the object portion, and does not necessarily mean positioned on the upper side of the object portion based on a gravitational direction.

In addition, unless explicitly described to the contrary, the word “comprise”, and variations such as “comprises” or “comprising”, will be understood to imply the inclusion of stated elements but not the exclusion of any other elements.

Further, in the specification, the phrase “on a plane” or “in a plane” means when an object portion is viewed from above, and the phrase “on a cross-section” or “in a cross-section” means when a cross-section taken by vertically cutting an object portion is viewed from the side.

Additionally, throughout the specification, two directions that are parallel to the upper surface of the substrate and intersect to each other are defined as a first direction D1 and a second direction D2, respectively, and the direction perpendicular to the upper surface of the substrate is described as a third direction D3. The first direction D1 and the second direction D2 may be perpendicular to each other. However, embodiments of the present disclosure are not necessarily limited thereto and the first to third directions D1 to D3 may cross each other at various different angles.

In drawings related to a semiconductor device according to an embodiment, by an example, a transistor including a nano wire or a nano sheet, for example, a multi-bridge channel field effect transistor (MBCFETTM), or a fin-type transistor (FinFET) including a channel pattern of a fin-type pattern shape is shown. However, embodiments of the present disclosure are not necessarily limited thereto. For example, the semiconductor devices according to several embodiments may include a tunneling transistor (a tunneling FET), a 3D stack field effect transistor (3DSFET), or a complementary field effect transistor (CFET).

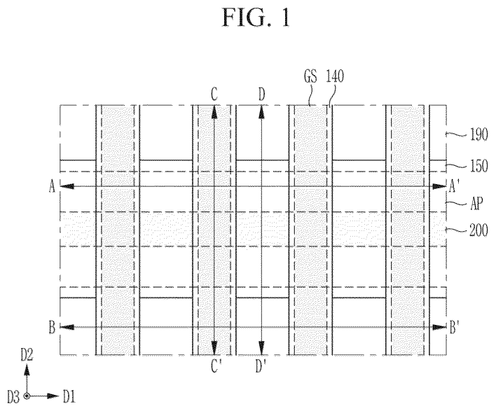

A semiconductor device according to an embodiment is described with reference to FIG. 1 to FIG. 8.

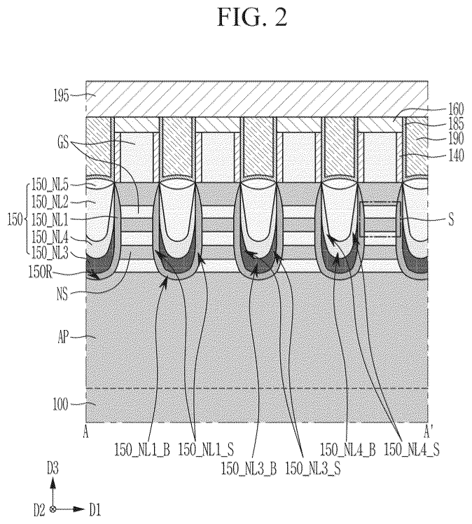

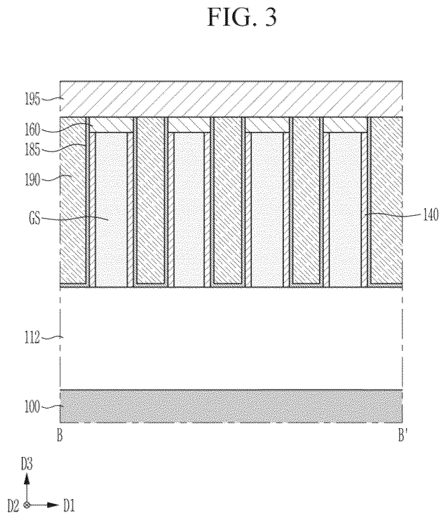

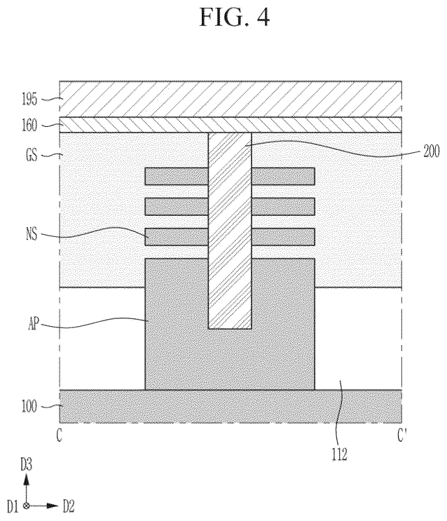

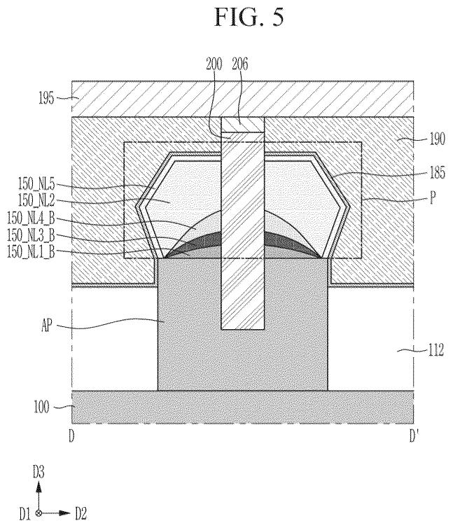

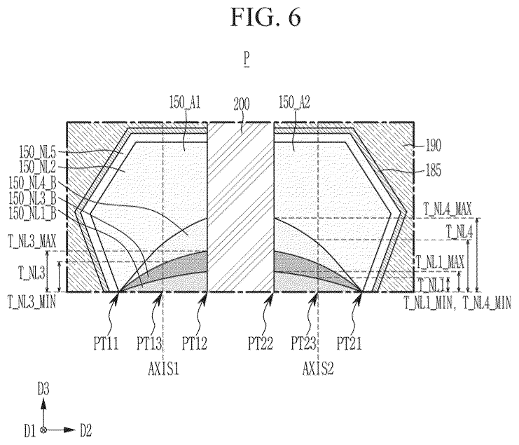

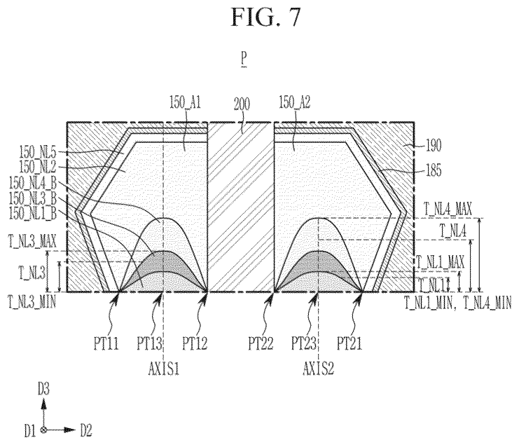

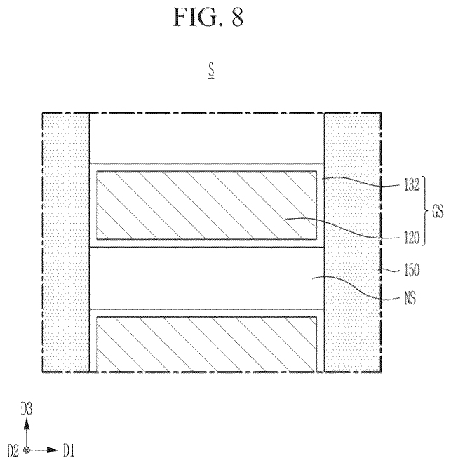

FIG. 1 is a top plan view showing a semiconductor device according to an embodiment. FIG. 2 is a cross-sectional view cut along a line A-A′ in FIG. 1. FIG. 3 is a cross-sectional view cut along a line B-B′ in FIG. 1. FIG. 4 is a cross-sectional view cut along a line C-C′ in FIG. 1. FIG. 5 is a cross-sectional view cut along a line D-D′ in FIG. 1. FIG. 6 is an enlarged cross-sectional view of a region P in FIG. 5. FIG. 7 is a cross-sectional view corresponding to FIG. 6. according to a reference example. FIG. 8 is an enlarged cross-sectional view of a region S of FIG. 2.

Referring to FIG. 1 to FIG. 8, in an embodiment a semiconductor device includes a substrate 100, an active pattern AP positioned on the substrate 100, a source/drain pattern including source/drain regions 150 positioned on the active pattern AP and spaced from each other, a channel pattern NS positioned on the active pattern AP and connecting (e.g., electrically connecting) the source/drain regions 150 to each other, a gate pattern GS crossing between the source/drain regions 150 (e.g., in a third direction D3 which is a thickness direction of the substrate 100) and surrounding the channel pattern NS, and a barrier rib 200 that separates the source/drain region 150 into a plurality of parts.

In an embodiment, the substrate 100 may include a bulk silicon or a silicon-on-insulator (SOI). Alternatively, the substrate 100 may include a silicon substrate, or other materials, such as silicon germanium (SiGe), silicon germanium on insulator (SGOI), indium antimonide, lead tellurium compound, indium arsenic, indium phosphide, gallium arsenic, or gallium antimony. As another example, substrate 100 may be an insulation substrate including an insulating material. However, embodiments of the present disclosure are not necessarily limited thereto.

The upper surface of the substrate 100 may be formed as a plane parallel to the first direction D1 and the second direction D2 that intersects the first direction D1. For example, in an embodiment the first to third directions D1 to D3 may be perpendicular to each other. However, embodiments of the present disclosure are not necessarily limited thereto and the first to third directions D1 to D3 may cross each other at various different angles.

The active pattern AP may be positioned on (e.g., disposed directly thereon) the substrate 100. In an embodiment, the active pattern AP may protrude from the substrate 100 (e.g., in the third direction D3). In an embodiment, the active pattern AP may extend longitudinally in the first direction D1. The active pattern AP may protrude from the upper surface of the substrate 100 in the third direction D3. In an embodiment, the active pattern AP may be arranged in plurality to be spaced apart from each other along the second direction D2.

As an example, the active pattern AP may be positioned in a region where a PMOS is formed. As another example, the active pattern AP may be positioned in the region where an NMOS is formed. For example, the active patterns AP arranged in plurality and spaced apart from each other along the second direction D2 may all be positioned in the region where the PMOS is formed, the active patterns AP arranged in plurality and spaced apart from each other along the second direction D2 may all be positioned in the region where the NMOS is formed, or the active patterns AP arranged in plurality and spaced apart from each other along the second direction D2 may be alternately positioned in the region where the PMOS is formed and the region where the NMOS is formed.

In an embodiment, the active pattern AP may be formed by etching a portion of the substrate 100, or may be an epitaxial layer grown from the substrate 100. However, embodiments of the present disclosure are not necessarily limited thereto. For example, in an embodiment, instead of the active pattern AP, an insulation pattern including an insulating material may be applied.

In an embodiment, the active pattern AP may include silicon (Si) or germanium (Ge) as an elemental semiconductor material. Additionally, the active pattern AP may include a compound semiconductor, for example, a group IV-IV compound semiconductor or a group III-V compound semiconductor. The Group IV-IV compound semiconductor may be, for example, binary compounds, or ternary compounds including carbon (C), silicon (Si), germanium (Ge), tin (Sn), or combinations thereof. The Group III-V compound semiconductors, for example, may be a binary compound, a ternary compound, or a quaternary compound formed by combining Group III elements such as aluminum (Al), gallium (Ga), indium (In), or a combination thereof, and Group V elements such as phosphorus (P), arsenic (As), and antimuonium (Sb), or a combination thereof. However, embodiments of the present disclosure are not necessarily limited thereto.

The channel pattern NS may be positioned on (e.g., disposed on) the upper surface of the active pattern AP. In an embodiment, the channel pattern NS may include a plurality of channels arranged separately from the active pattern AP in the third direction D3. For example, a plurality of channels spaced apart from each other in the third direction D3 may be positioned on one active pattern AP. Here, the third direction D3 may be a direction that intersects the first direction D1 and the second direction D2. For example, third direction D3 may be the thickness direction of substrate 100.

As an example, in FIG. 2 and FIG. 4, three channels are shown as being stacked and spaced apart along the third direction D3. However, embodiments of the present disclosure are not necessarily limited thereto and the number of the channels may vary. For example, in an embodiment two channels may be stacked apart from each other along the third direction D3, or four or more channels may be stacked apart from each other along the third direction D3.

Additionally, as an example, In FIG. 4, the sides (e.g., lateral ends) of the channels are shown as flat and aligned with each other along the third direction D3. However, embodiments of the present disclosure are not necessarily limited thereto. For example, in some embodiments the sides of the channels may be a combination of curved and flat surfaces, or they may be entirely curved and at least some channels may not be aligned with each other along the third direction D3.

In an embodiment, the channel pattern NS may include a semiconductor material and may have a nano sheet shape with a thickness of several nanometers. In an embodiment, the channel pattern NS may include elemental semiconductor materials such as silicon (Si), silicon germanium (SiGe), Group IV-IV compound semiconductors, or Group III-V compound semiconductors. Each channel may include the same material as the active pattern AP, or it may include a material different from the active pattern AP.

In some embodiments, the active pattern AP may be a silicon lower pattern including silicon (Si), and the channel pattern NS may be a silicon sheet pattern including silicon (Si).

In an embodiment, the field insulation layer 112 may be positioned on (e.g., disposed directly thereon) the substrate 100. The field insulation layer 112 may be positioned between the active patterns AP (e.g., in the second direction D2). For example, the field insulation layer 112 may be directly adjacent to the active pattern AP in the second direction D2. The field insulation layer 112 may not be positioned on (e.g., disposed on) the upper surface of the active pattern AP. The field insulation layer 112 may cover a partial or entire surface of the active pattern AP. In an embodiment, the channel pattern NS may be positioned higher in the third direction than the upper surface of the field insulation layer 112.

In an embodiment, the field insulation layer 112 may include an insulating material, for example, silicon oxide (SiO₂), silicon nitride (SIN), silicon oxynitride (SiON), or a combination thereof. The field insulation layer 112 is shown as a single layer. However, embodiments of the present disclosure are not necessarily limited thereto.

The barrier rib 200 may be positioned above the active pattern AP (e.g., in the third direction D3). As shown in FIG. 4, the barrier rib 200 may extend to the inside of the active pattern AP in the third direction D3.

In an embodiment, the barrier rib 200 extends longitudinally in the first direction D1 along the active pattern AP. The barrier rib 200 extends to pass through a source/drain region 150, which will be described later in the third direction D3. Accordingly, the barrier rib 200 may separate the source/drain region 150 into a plurality of parts. As an example, as shown in FIG. 5, one source/drain region 150 may have a first part 150_A1 and a second part 150_A2 of the source/drain region 150 separated to the left and right in the second direction D2 centered on the barrier rib 200, respectively. For example, the barrier rib 200 may be positioned between the sides of the first part 150_A1 and the second direction D2 of the second part 150_A2 of the source/drain region 150. In an embodiment, the barrier rib 200 may be in direct contact with the sides (e.g., lateral ends) of the first part 150_A1 and the second part 150_A2 of the source/drain region 150.

In addition, the barrier rib 200 may further extend in the third direction D3, penetrate the etch stop layer 185 covering the source/drain region 150, and be positioned within the interlayer insulating layer 190 positioned above the source/drain region 150 (e.g., in the third direction D3).

In an embodiment, the upper surface of the barrier rib 200 may be positioned at a higher level (e.g., in the third direction D3) than the upper surface of the source/drain region 150. For example, the upper surface of the barrier rib 200 may be positioned farther from the upper surface of the substrate 100 in the third direction D3 than the upper surface of the source/drain region 150. Accordingly, the barrier rib 200 may penetrate the source/drain region 150 and protrude in the third direction D3 (e.g., into the interlayer insulating layer 190).

As the barrier rib 200 extends along the active pattern AP in the first direction D1, the barrier rib 200 also passes between the channel pattern NS and the gate pattern GS. Additionally, the barrier rib 200 extends to penetrate the channel pattern NS in the third direction D3, so that the channel pattern NS may be separated into a plurality of parts.

The barrier rib 200 may be positioned between the sides (e.g., lateral ends) in the second direction D2 of the channel pattern NS. In an embodiment, the barrier rib 200 may be in direct contact with the side (e.g., lateral end) of the channel pattern NS. Additionally, the barrier rib 200 may be in direct contact with the side (e.g., lateral end) of the gate pattern GS positioned between adjacent channel patterns NS in the third direction D3. For example, the side surface of the barrier rib 200 may be in direct contact with the side surface of the stacking structure in which the gate pattern GS and the channel pattern NS are alternately stacked (e.g. in the third direction D3).

The upper surface of the barrier rib 200 may be positioned at a higher level (e.g., in the third direction D3) than the upper surface of the uppermost channel of the channel pattern NS. For example, the upper surface of the barrier rib 200 may be positioned farther from the upper surface of the substrate 100 in the third direction D3 than the upper surface of the uppermost channel of the channel pattern NS. The barrier rib 200 may protrude through an entirety of the channel pattern NS in the third direction D3.

In an embodiment, the upper surface of the barrier rib 200 may be positioned at a substantially equivalent level to the upper surface of the gate pattern GS. However, embodiments of the present disclosure are not necessarily limited thereto, and the barrier rib 200 may penetrate the upper surface of the gate pattern GS and protrude from the upper surface of the gate pattern GS in the third direction D3. For example, the upper surface of the barrier rib 200 may be positioned at a higher level in the third direction D3 than the upper surface of gate pattern GS.

In an embodiment, the upper surface of the barrier rib 200 may be in direct contact with the gate capping layer 160 positioned above the gate pattern GS. Alternatively, in an embodiment the upper surface of the barrier rib 200 may be positioned within the gate capping layer 160 positioned above the gate pattern GS, or the barrier rib 200 may entirely penetrate the gate capping layer 160 (e.g., in the third direction D3).

In an embodiment, the barrier rib 200 may include a low dielectric constant material. The barrier rib 200 may include a material having an etch selectivity for the channel pattern NS. In an embodiment, the barrier rib 200 may include, for example, silicon nitride (SiN), silicon carbon nitride (SiCN), silicon carbon oxide (SiOC), or low dielectric constant material. However, embodiments of the present disclosure are not necessarily limited thereto. In an embodiment, the low dielectric constant material, for example, may include fluorinated tetraethylorthosilicate (FTEOS), hydrogen silsesquioxane (HSQ), bis-benzocyclobutene (BCB), tetramethylorthosilicate (TMOS), octamethyleyclotetrasiloxane (OMCTS), hexamethyldisiloxane (HMDS), trimethylsilyl borate (TMSB), diacetoxyditertiarybutosiloxane (DADBS), trimethylsilil phosphate (TMSP), polytetrafluoroethylene (PTFE), tonen silazen (TOSZ), fluoride silicate glass (FSG), polyimide nanofoams such as polypropylene oxide, carbon doped silicon oxide (CDO), organo silicate glass (OSG), SiLK, amorphous fluorinated carbon, silica aerogels, silica xerogels, mesoporous silica, or a combination thereof. However, embodiments of the present disclosure are not necessarily limited thereto.

If the distance between the channel patterns NS adjacent in the second direction D2 is reduced, a coupling (e.g., an electrical connection) may occur between the channel patterns NS adjacent to each other in the second direction D2. Accordingly, the reliability of the semiconductor device may decrease. In the semiconductor device according to some embodiments, the barrier rib 200 includes the low dielectric constant material, so that the coupling that occurs between the channel patterns NS adjacent in the second direction D2 may be reduced. Therefore, the integration of the semiconductor devices may be further increased.

In an embodiment, the semiconductor device may further include a barrier rib capping layer 206.

The barrier rib capping layer 206 may be positioned on (e.g., disposed directly thereon) the barrier rib 200. The barrier rib capping layer 206 may be positioned between (e.g., disposed directly therebetween) the barrier rib 200 and the upper insulation layer 195 in the third direction D3. For example, the barrier rib capping layer 206 may overlap with the barrier rib 200 in the third direction D3. The lower surface of the barrier rib capping layer 206 may be in direct contact with the barrier rib 200. The upper surface of the barrier rib capping layer 206 may be in direct contact with the upper insulation layer 195.

In an embodiment, the barrier rib capping layer 206 may be positioned on the portion where the barrier rib 200 passes through the source/drain region 150, and may not be positioned on the portion where the barrier rib 200 passes through the channel pattern NS.

In an embodiment, the barrier rib capping layer 206, for example, may include silicon oxide (SiO₂), silicon nitride (SiN), silicon oxynitride (SiON), a low dielectric constant material, or a combination thereof.

In FIG. 5, the barrier rib capping layer 206 is displayed separately from the interlayer insulating layer 190. However, embodiments of the present disclosure are not necessarily limited thereto. For example, in an embodiment the barrier rib capping layer 206 may not be distinguished from the interlayer insulating layer 190. For example, the barrier rib capping layer 206 and the interlayer insulating layer 190 include the same material and may be integral with each other, so a boundary may not be formed between two structures.

A gate pattern GS may be positioned on (e.g., disposed on) the substrate 100. In an embodiment, the gate pattern GS may extend longitudinally in the second direction D2. The gate pattern GS may be arranged to be spaced apart in the first direction D1.

The gate pattern GS may be positioned above the active pattern AP. The gate pattern GS may cross the active pattern AP on a plane.

In an embodiment, the gate pattern GS may surround at least a portion of each channel of the channel pattern NS. For example, the gate pattern GS may surround at least a portion of the channel pattern NS by covering one side, the lower surface, and the upper surface of the channel. Accordingly, one side, the lower surface, and the upper surface of the channel may each be in direct contact with the gate pattern GS. In an embodiment, another side of the channel pattern NS may be in direct contact with the barrier rib 200.

Additionally, the gate pattern GS may be in direct contact with at least a portion of the side (e.g., a lateral side) of the barrier rib 200. However, the gate pattern GS may not cover the upper surface of the barrier rib 200. As described above, the barrier rib 200 may extend to penetrate the gate pattern GS in the third direction D3, separate the gate pattern GS into a plurality of parts, and be in direct contact with the side of the gate pattern GS. For example, since the side surface of the barrier rib 200 is in direct contact with the side surface of the gate pattern GS, the gate pattern GS may not cover the upper surface of the barrier rib 200.

In an embodiment, each gate pattern GS may include a plurality of sub-gate structures and main gate structures.

The plurality of sub-gate structures may be positioned between the adjacent channels in the third direction D3 of the channel pattern NS. As an example, the channel pattern NS may include a plurality of channels, and the gate pattern GS may include a plurality of sub-gate structures. In an embodiment, the number of the plurality of sub-gate structures may be proportional to the number of the channels included in the channel pattern NS. For example, the number of the plurality of sub-gate structures may be the same as the number of the channels in the channel pattern NS. For example, as shown in FIG. 2 and FIG. 4, the number of the plurality of sub-gate structures and the plurality of channels may each be 3. However, embodiments of the present disclosure are not necessarily limited thereto and four or more sub-gate structures and channels may be included in some embodiments. The sub-gate structure may be positioned between the upper surface of one channel and the lower surface of another channel facing it in the third direction D3. The sub-gate structure may be positioned between the upper surface of the active pattern AP and the lower surface of the lowermost channel facing in the third direction D3.

Additionally, the sub-gate structure may be adjacent to a source/drain region 150, which will be explained later, in the first direction D1.

The main gate structure may be positioned above the sub-gate structure and the channel pattern NS (e.g., in the third direction D3). For example, in an embodiment the main gate structure may be positioned above the channel positioned at the uppermost of the channel pattern NS. Additionally, the main gate structure may be positioned in the third direction D3 between the channel patterns NS spaced apart from each other in the second direction D2.

For example, the main gate structure may be positioned on (e.g., disposed directly thereon) the upper surface of the channel pattern NS in the region that intersects the active pattern AP, and may be positioned on (e.g., disposed directly thereon) the field insulation layer 112 in the region that does not intersect with the active pattern AP.

In an embodiment, referring to FIG. 8, the gate pattern GS may include a gate insulating layer 132 and a gate electrode 120.

The gate electrode 120 may be positioned above the active pattern AP. The gate electrode 120 may intersect with the active pattern AP.

The gate electrode 120 may surround at least a portion of each channel of the channel pattern NS. The gate electrode 120 may surround at least a portion of the barrier rib 200.

For example, the gate electrode 120 may surround at least a portion of the channel pattern NS by covering one side, the lower surface, and the upper surface of the channel. Accordingly, three surfaces of the channel pattern NS may be surrounded by the gate electrode 120. Additionally, the gate electrode 120 may be in direct contact with a portion of the side surface of the barrier rib 200.

The gate electrode 120 may be positioned between the adjacent source/drain regions 150 in the first direction D1. For example, the source/drain regions 150 may be positioned on both sides in the first direction D1 with the gate electrode 120 as a reference.

In an embodiment, the gate electrode 120 may include a metal, a metal alloy, a conductive metal nitride, a metal silicide, a doped semiconductor material, a conductive metal oxide, or a conductive metal oxynitride. In an embodiment, the gate electrode 120, for example, may include titanium nitride (TiN), tantalum carbide (TaC), tantalum nitride (TaN), titanium silicon nitride (TiSiN), tantalum silicon nitride (TaSiN), tantalum titanium nitride (TaTiN), titanium aluminum nitride (TiAlN), tantalum aluminum nitride (TaAlN), tungsten nitride (WN), ruthenium (Ru), titanium aluminum (TiAl), titanium aluminum nitride (TiAlC—N), titanium aluminum carbide (TiAlC), titanium carbide (TiC), tantalum nitride (TaCN), tungsten (W), aluminum (Al), copper (Cu), cobalt (Co), titanium (Ti), tantalum (Ta), nickel (Ni), platinum (Pt), nickel platinum (Ni—Pt), niobium (Nb), niobium nitride (NbN), niobium carbide (NbC), molybdenum (Mo), molybdenum nitride (MoN), molybdenum carbide (MoC), tungsten carbide (WC), rhodium (Rh), palladium (Pd), iridium (Ir), osmium (Os)), silver (Ag), gold (Au), zinc (Zn), vanadium (V), or a combination thereof. However, embodiments of the present disclosure are not necessarily limited thereto. A conductive metal oxide and a conductive metal oxynitride may include oxidized forms of the materials described above. However, embodiments of the present disclosure are not necessarily limited thereto.

The gate insulating layer 132 may be positioned along the circumference of at least a portion of the channel pattern NS. In an embodiment, the gate insulating layer 132 may be in direct contact with the active pattern AP, the source/drain pattern, and the channel pattern NS. In an embodiment, the gate insulating layer 132, for example, may include silicon oxide (SiO₂), a high dielectric constant material, or a combination thereof.

As an example, in an embodiment the gate insulating layer 132 may include a plurality of layers. In an embodiment, the gate insulating layer 132 may include a layer made of silicon oxide (SiO₂) and a layer made of a material having a higher dielectric constant than silicon oxide (SiO₂). For example, the material having a higher dielectric constant than silicon oxide (SiO₂) may be oxide (HfO), aluminum oxide (AlO), or tantalum oxide (TaO). In this embodiment, the layer made of silicon oxide (SiO₂) may be in direct contact with the channel pattern NS and the layer made of the material having a higher dielectric constant than silicon oxide (SiO₂) may be in direct contact with the gate electrode 120.

In an embodiment, the semiconductor device may further include a gate spacer 140.

The gate spacer 140 may be positioned on the side (e.g., a lateral side) of the gate pattern GS. For example, the gate spacer 140 may be positioned between the gate pattern GS and the interlayer insulating layer 190 (e.g., in the first direction D1). Additionally, as an example, the gate spacer 140 may be positioned between the source/drain region 150 and the gate pattern GS.

The gate spacer 140 may not be positioned between the active pattern AP and the channel pattern NS. In an embodiment, the gate spacer 140 may not be positioned between the channel patterns NS adjacent in the third direction D3. However, embodiments of the present disclosure are not necessarily limited thereto, and the gate spacer 140 may be positioned between the channel patterns NS adjacent in the third direction D3 or between the active pattern AP and the channel pattern NS adjacent in the third direction D3 in some embodiments.

As an example, in an embodiment the gate spacer 140 may include silicon nitride (SiN), silicon oxynitride (SiON), silicon oxide (SiO₂), silicon carbonate nitride (SiOCN), silicon boron nitride (SiBN), silicon acid boron nitride (SiOBN), silicon oxycarbide (SiOC), or a combination thereof.

In an embodiment, the semiconductor device may further include a gate capping layer 160 on the gate pattern GS (e.g., directly thereon in the third direction D3). The gate capping layer 160 may be positioned above the gate pattern GS and the gate spacer 140. Alternatively, the gate capping layer 160 may be positioned only above the gate pattern GS and may not be positioned directly above the gate spacer 140.

In an embodiment, the gate capping layer 160 may include a material having an etch selectivity against the interlayer insulating layer 190. In an embodiment the gate capping layer 160 may include, for example, silicon nitride (SiN), silicon oxynitride (SiON), silicon carbide nitride (SiCN), silicon carbonate nitride (SiOCN), or a combination thereof.

The source/drain pattern may be placed on (e.g., disposed on) the active pattern AP. The source/drain pattern includes a plurality of source/drain regions of 150 that are spaced apart from each other in the first direction D1.

The source/drain regions 150 may be positioned on both sides (e.g., lateral sides) in the first direction D1 of the gate pattern GS. Therefore, the source/drain region 150 may be in direct contact with the side (e.g., lateral end) of the channel pattern NS. The source/drain region 150 may be connected to (e.g., electrically connected thereto) the channel pattern NS. The source/drain region 150 may perform a role of a source/drain of a transistor that uses the channel pattern NS as a channel region.

In an embodiment, the source/drain region 150 may be positioned within the source/drain recess 150R with a depth along the third direction D3. The source/drain region 150 may fill the source/drain recess 150R. The lower surface of the source/drain recess 150R may be defined by the active pattern AP. The sides of the source/drain recess 150R may be defined by the interlayer insulating layer 190.

As shown in FIG. 2, the upper surface of the source/drain region 150 may be positioned at a higher level (e.g., in the third direction D3) than the upper surface of the channel pattern NS. For example, in an embodiment the upper surface of the source/drain region 150 may be positioned farther from the upper surface of the substrate 100 than the upper surface of the channel pattern NS. Additionally, in an embodiment the source/drain region 150 may protrude in the second direction D2 rather than the channel pattern NS. For example, the width of the second direction D2 of the source/drain region 150 may be larger than the width of the second direction D2 of the channel pattern NS.

As shown in FIG. 2, the exterior side of the source/drain region 150 may be in direct contact with the channel pattern NS in the first direction D1, the gate insulating layer 132 in the first direction D1, and the active pattern AP in the third direction D3. In an embodiment, the exterior side of the source/drain region 150 may be made of an uneven curved surface. For example, the portion of the exterior side of the source/drain region 150 that directly contacts the channel pattern NS may have a concave or approximately flat shape in a cross-sectional view (e.g., in a plane defined in the first and third directions D1, D3). The portion of the exterior side of the source/drain region 150 that is in direct contact with the gate insulating layer 132 may have a convex shape. In an embodiment, after forming the source/drain recess 150R, the shape of the source/drain recess 150R may be formed to be uneven by further performing a process of selectively etching the dummy gate structure. Accordingly, the shape of the exterior side of source/drain region 150 may be determined by the etching process.

In FIG. 5, only one source/drain region 150 is shown, but other source/drain regions

150 may be positioned adjacent to the source/drain region 150 in the second direction D2. In this embodiment, the source/drain regions 150 adjacent in the second direction D2 may all include a semiconductor material doped with an n-type impurity, and the source/drain regions 150 adjacent in the second direction D2 may all include a semiconductor material doped with a p-type impurity, or one of the source/drain regions 150 adjacent in the second direction D2 may include a semiconductor material doped with an n-type impurity, and the other may include a semiconductor material doped with a p-type impurity. However, in an embodiment in one source/drain region 150, both the first part 150_A1 and the second part 150_A2 may be doped with an n-type impurity, or both may be doped with a p-type impurity.

As an example, in an embodiment the n-type impurity may include phosphorus (P), arsenic (As), antimony (Sb), or a combination thereof. For example, in an embodiment in which phosphorus (P) is use as the n-type impurity, phosphorus (P) or phosphine PH3 may be used as the impurity gas and phosphorus (P) may be doped into the semiconductor materials through a low energy ion implantation method, a plasma ion implantation method, or a pulsed laser ablation deposit method.

In an embodiment, the p-type impurity may include boron (B), aluminum (Al), gallium (Ga), indium (In), or combinations thereof. For example, in an embodiment in which boron (B) is used as the p-type impurity, boron (B), boron difluoride (BF2), or boron trifluoride (BF3) may be used as the impurity gas, and boron (B) may be doped into the semiconductor materials through a low energy ion implantation, a plasma ion implantation, or a pulsed laser ablation deposition.

As described above, the barrier rib 200 extends to penetrate the source/drain region 150 in the third direction D3, so that the source/drain region 150 may be separated into a plurality of parts. As an example, as shown in FIG. 5 and FIG. 6, one source/drain region 150 may have a first part 150_A1 and a second part 150_A2 of the source/drain region 150 separated to the left and right in the second direction D2 centered on the barrier rib 200. For example, the barrier rib 200 may be positioned between the sides (e.g., lateral ends) in the second direction D2 of the first part 150_A1 and the second part 150_A2 of the source/drain region 150.

Here, “one source/drain region 150” is formed by the same epitaxial growth process before forming the barrier rib 200, as will be described later, and refers to the source/drain region 150 divided into the first part 150_A1 and the second part 150_A2 as the barrier rib 200 is formed. Since the first part 150_A1 and the second part 150_A2 of one source/drain region 150 may each function independently as a source/drain, one source/drain region 150 is not necessarily limited to meaning one source/drain of the transistor.

Parts 150_A1 and 150_A2 of each source/drain region 150 include a first epitaxial layer 150_NL1 within the source/drain recess 150R, and a second epitaxial layer 150_NL2 disposed on the first epitaxial layer 150_NL1.

In an embodiment, the first epitaxial layer 150_NL1 has a lower end 150_NL1_B positioned above (e.g., disposed directly above) the active pattern AP and a sidewall part 150_NL1_S extending from the lower end 150_NL1_B in the third direction D3.

As an example, in an embodiment the sidewall part 150_NL1_S of the first epitaxial layer 150_NL1 may be defined from the portion in direct contact with the lower end of the channel positioned at the lowermost of the channel pattern NS in third direction D3 to the uppermost of the first epitaxial layer 150_NL1. The lower end 150_NL1_B may be defined from the portion in direct contact with the lower end of the channel positioned at the lowermost of the channel pattern NS to the portion in direct contact with the active pattern AP.

The sidewall part 150_NL1_S of the first epitaxial layer 150_NL1 extends in the third direction D3 and is connected to (e.g., directly connected thereto) the channel pattern NS. For example, the sidewall part 150_NL1_S of the first epitaxial layer 150_NL1 may extend to the upper end of the source/drain recess 150R and cover the channels of the channel pattern NS and the sides of the sub-gate structures of the gate pattern GS. The sidewall part 150_NL1_S of the first epitaxial layer 150_NL1 may extend continuously in the third direction D3 along the side of the source/drain recess 150R. The sidewall part 150_NL1_S of the first epitaxial layer 150_NL1 may be in direct contact with the sides (e.g., lateral ends) of the channels of the channel pattern NS.

The second epitaxial layer 150_NL2 may be positioned above the first epitaxial layer 150_NL1 in the third direction D3.

The second epitaxial layer 150_NL2 may be positioned between the sidewall part 150_NL1_S of the first epitaxial layer 150_NL1 in the first direction D1. The second epitaxial layer 150_NL2 may fill the space of the source/drain recess 150R remaining after the first epitaxial layer 150_NL1 is formed. As shown in FIG. 5 and FIG. 6, in an embodiment the second epitaxial layer 150_NL2 may grows laterally in the second direction D2 during an epitaxial growth, so that the second epitaxial layer 150_NL2 has a convex diamond shape on the left and right sides (e.g., in the second direction D2).

In an embodiment, the second epitaxial layer 150_NL2 may not be in direct contact with the channel pattern NS, the plurality of sub-gate structure, and the active pattern AP. For example, in an embodiment the sidewall part 150_NL1_S of the first epitaxial layer 150_NL1 may be positioned between the second epitaxial layer 150_NL2, and the channel pattern NS and the plurality of sub-gate structures. The lower end 150_NL1_B of the first epitaxial layer 150_NL1 may be positioned between the second epitaxial layer 150_NL2 and the active pattern AP (e.g., in the third direction D3).

In an embodiment, the first epitaxial layer 150_NL1 and the second epitaxial layer 150_NL2 may include different compositions from each other. For example, in an embodiment the first epitaxial layer 150_NL1 and the second epitaxial layer 150_NL2 may include silicon germanium (SiGe), silicon (Si), or silicon carbide (SiC).

As an example, the source/drain region 150 may include SiGe. The Ge content of the first epitaxial layer 150_NL1 may be different from the Ge content of the second epitaxial layer 150_NL2. In an embodiment, the first epitaxial layer 150_NL1 may be made of SiGe including a low concentration Ge, and the second epitaxial layer 150_NL2 may be made of SiGe including a high concentration Ge. The Ge content of the first epitaxial layer 150_NL1 may be lower than the Ge content of the second epitaxial layer 150_NL2. In an embodiment, the difference between the Ge content of the first epitaxial layer 150_NL1 and the Ge content of the second epitaxial layer 150_NL2 may be greater than or equal to about 20%. However, the material of the source/drain region 150 is not necessarily limited to this and may be changed in various ways.

For example, in an embodiment the first epitaxial layer 150_NL1 may have a first impurity, and the second epitaxial layer 150_NL2 may include a second impurity that is different from the first impurity.

In the composition of the first epitaxial layer 150_NL1, the first impurity may be selected as an element having a lower diffusivity (e.g., a diffusion coefficient) than the diffusivity (e.g., a diffusion coefficient) of the second impurity. For example, in an embodiment in which an NMOS transistor is formed, the first impurity may include arsenic (As), antimony (Sb), or a combination thereof, and the second impurity may include phosphorus (P). For example, in an embodiment the impurity concentration of the second epitaxial layer 150_NL2 may be in a range of about 1.5 times to about 15 times the impurity concentration of the first epitaxial layer 150_NL1.

In an embodiment, a plurality of epitaxial layers may be further positioned between the first epitaxial layer 150_NL1 and the second epitaxial layer 150_NL2. As an example, as shown in FIG. 2, FIG. 5, and FIG. 6, the third epitaxial layer 150_NL3 and the fourth epitaxial layer 150_NL4 may be further positioned between the first epitaxial layer 150_NL1 and the second epitaxial layer 150_NL2.

In an embodiment, each of the third epitaxial layer 150_NL3 and the fourth epitaxial layer 150_NL4 may have, like the first epitaxial layer 150_NL1, a lower end 150_NL3_B and 150_NL4_B and a sidewall part 150_NL3_S and 150_NL4_S extending from the lower end 150_NL3_B and 150_NL4_B in the third direction D3. In an embodiment, the lower end 150_NL3_B of the third epitaxial layer 150_NL3 is positioned above (e.g., dispose directly above in the third direction D3) the lower end 150_NL1_B of the first epitaxial layer 150_NL1, and the sidewall part 150_NL3_S extends in the third direction D3 and is connected to (e.g., directly connected thereto) the sidewall part 150_NL1_S of the first epitaxial layer 150_NL1. The lower end 150_NL4_B of the fourth epitaxial layer 150_NL4 is positioned above (e.g., disposed directly above in the third direction D3) the lower end 150_NL3_B of the third epitaxial layer 150_NL3, and the sidewall part 150_NL3_S extends in the third direction D3 and is connected to (e.g., directly connected thereto) the sidewall part 150_NL3_S of the third epitaxial layer 150_NL3.

Additionally, the fifth epitaxial layer 150_NL5 may be further positioned above (e.g., disposed directly above in the third direction D3) the second epitaxial layer 150_NL2. The fifth epitaxial layer 150_NL5 may cover the surface of the second epitaxial layer 150_NL2. The fifth epitaxial layer 150_NL5 may position the upper surface of the source/drain region 150 at a higher level than the upper surface of the channel pattern NS.

In an embodiment, the third epitaxial layer 150_NL3, the fourth epitaxial layer 150_NL4, and the fifth epitaxial layer 150_NL5 may have different compositions than the first epitaxial layer 150_NL1 and the second epitaxial layer 150_NL2, respectively. As an example, in an embodiment the third epitaxial layer 150_NL3, the fourth epitaxial layer 150_NL4, and the fifth epitaxial layer 150_NL5 may each include silicon germanium (SiGe), and the germanium (Ge) concentration of the third epitaxial layer 150_NL3, the fourth epitaxial layer 150_NL4, and the fifth epitaxial layer 150_NL5 may be different from the germanium (Ge) concentration of the first epitaxial layer 150_NL1 and the second epitaxial layer 150_NL2, respectively. For example, in an embodiment the germanium (Ge) concentration may be higher in the following order of the second epitaxial layer 150_NL2, the fourth epitaxial layer 150_NL4, the third epitaxial layer 150_NL3, and the first epitaxial layer 150_NL1. The fifth epitaxial layer 150_NL5 may have a higher or lower germanium (Ge) concentration than the second epitaxial layer 150_NL2. However, embodiments of the present disclosure are not necessarily limited thereto.

In an embodiment, the third epitaxial layer 150_NL3, the fourth epitaxial layer 150_NL4, and the fifth epitaxial layer 150_NL5 may include impurities that are different from those of the first epitaxial layer 150_NL1 and the second epitaxial layer 150_NL2. For example, in an embodiment the third epitaxial layer 150_NL3, the fourth epitaxial layer 150_NL4, and the fifth epitaxial layer 150_NL5 may include silicon germanium (SiGe), silicon (Si), silicon carbide (SiC), or a combination thereof.

In an embodiment, as described later, as the source/drain region 150 is formed using the epitaxial growth method, the lower end 150_NL1_B of the first epitaxial layer 150_NL1 has a thickness profile in which the thickness T_NL1 changes along the second direction D2.

As an example, a cross-section (hereinafter, referred to as “first cross-section image”) cut in the second direction D2 and the third direction D3 at the center of the first direction D1 of the source/drain region 150, for example, as shown in FIG. 5 and FIG. 6, a profile according to the second direction D2 of the lower end 150_NL1_B of the first epitaxial layer 150_NL1 is shown.

Additionally, as will be described later, in the semiconductor devices according to some embodiments, after forming the source/drain regions 150, the barrier ribs 200 are formed. Accordingly, defects caused by heterogeneous interfaces with the barrier rib may be reduced when growing the epitaxial layer of the source/drain region 150.

In an embodiment, prior to forming the barrier rib 200, when the source/drain region 150 is formed (e.g., without the presence of the barrier rib 200), the first epitaxial layer 150_NL1 is formed so that the lower end 150_NL1_B in the first cross-section has a shape that is convex upwardly in the third direction D3, for example, a bell shape. For example, in an embodiment the thickness T_NL1 of the lower end 150_NL1_B of the first epitaxial layer 150_NL1 may have a form in which the thickness T_NL1 increases from one end of the active pattern AP to the other end in the second direction D2, after reaching a maximum value T_NL1_MAX at approximately the midpoint of the second direction D2 of the active pattern, and the thickness T_NL1 decreases as it moves towards the other end of the active pattern AP.

Afterwards, by forming the barrier rib 200 and dividing the source/drain region 150 into, for example, the first part 150_A1 and the second part 150_A2, in the first part 150_A1 and the second part 150_A2 of the source/drain region 150, the thickness T_NL1 of the lower end 150_NL1_B of the first epitaxial layer 150_NL1 has a shape that decreases as it approaches a first point PT11 and PT21, which is positioned furthest from the barrier rib 200 in the second direction D2, and increases as it approaches a second point PT12 and PT22, which meets the barrier rib 200.

Here, the first points PT11 and PT21 and the second points PT12 and PT22 may be positioned on the upper surface of the active pattern AP. The first point PT11 and PT21 is a point located on the upper surface of the active pattern AP in the first cross-section and positioned furthest from barrier rib 200 in the second direction D2, and the second point PT12 and PT22 is a point located on the upper surface of the active pattern AP in the first cross-section and is in direct contact with the barrier rib 200.

In some embodiments, in the first cross-section, that is, as one example, in FIG. 5 and FIG. 6, parts 150_A1 and 150_A2 of the source/drain region 150 have an asymmetric shape at the lower end 150_NL1_B of the first epitaxial layer 150_NL1 around an axis AXIS1 and AXIS2 extending in the third direction D3.

Here, the axes AXIS1 and AXIS2 may be an axis that passes through a point positioned on the upper surface of the active pattern AP in the first cross-section and extends in the third direction D3. For example, the axes AXIS1 and AXIS2 may be axes positioned on the upper surface of the active pattern AP in the first cross-section and extending in the third direction D3 while passing a third point PT13 and PT23 positioned at the middle of the first point PT11 and PT21 and the second point PT12 and PT22 in the second direction D2.

As described above, in the first cross-section of each of the first part 150_A1 and the second part 150_A2 of the source/drain region 150, the thickness T_NL1 of the lower end 150_NL1_B of the first epitaxial layer 150_NL1 has a profile that increases as it approaches from the first point PT11 and PT21 towards the second point PT12 and PT22. Therefore, in the first cross-section of the parts 150_A1 and 150_A2 of the source/drain region 150, the shape of the lower end 150_NL1_B of the first epitaxial layer 150_NL1 does not have the axis AXIS1 and AXIS2 that are symmetrical in the second direction D2.

In an embodiment, in the first cross-section, the first part 150_A1 and the second part 150_A2 of the source/drain region 150 have a symmetrical shape with the thickness T_NL1 profile of the lower end 150_NL1_B of the first epitaxial layer 150_NL1 centered on the barrier rib 200. For example, the thickness T_NL1 profile of the lower end 150_NL1_B of the first epitaxial layer 150_NL1 is symmetrical (e.g., a mirror image) with the barrier rib 200 as the central axis for the first part 150_A1 and the second part 150_A2 of the source/drain region 150.

As described above, in the semiconductor device according to some embodiments, after forming the source/drain region 150, the barrier rib 200 is formed. In the absence of the barrier rib 200, when the source/drain region 150 is formed, the first epitaxial layer 150_NL1 is formed to have a shape in which the lower end 150_NL1_B is convex upward toward the third direction D3 in the first cross-section, for example, a bell shape. Afterwards, by forming the barrier rib 200 and dividing the source/drain region 150 into, for example, the first part 150_A1 and the second part 150_A2, in the first cross-section, the thickness profile of the lower end 150_NL1_B of the first epitaxial layer 150_NL1 is symmetrical around the barrier rib 200, but in each of the first part 150_A1 and the second part 150_A2, the thickness profile of the lower end 150_NL1_B of the first epitaxial layer 150_NL1 is asymmetric about the axes AXIS1 and AXIS2 extending in the third direction D3.

In an embodiment, FIG. 7 is a cross-sectional view corresponding to FIG. 6 according to a reference example. FIG. 7 is the cross-sectional view showing a comparative embodiment in which the barrier rib 200 is formed first and then the source/drain region 150 is formed.

Referring to FIG. 7, if the barrier rib 200 is formed first, defects caused by heterogeneous interfaces with the barrier rib 200 may occur during the growth of the epitaxial layer of the source/drain region 150. In addition, if the first epitaxial layer 150_NL1 is formed separately in each region divided by the barrier rib 200, the first epitaxial layer 150_NL1 of each of the first part 150_A1 and the second part 150_A2 of the source/drain region 150 is formed to have a shape in which the lower end 150_NL1_B is convex upwardly in the third direction D3, for example, a bell shape. Accordingly, in this comparative embodiment, in the first cross-section, the thickness profile of the lower end 150_NL1_B of the first epitaxial layer 150_NL1 is symmetrical around the barrier rib 200, even in each of the first part 150_A1 and the second part 150_A2, the thickness profile of the lower end 150_NL1_B of the first epitaxial layer 150_NL1 is symmetrical about the axes AXIS1 and AXIS2 extending in the third direction D3.

Here, the symmetry means that the tendency of the profile is substantially symmetrical, and does not mean that two shapes are completely the same. For example, in the first part 150_A1 and the second part 150_A2 of the source/drain region 150, if the shape of the lower end 150_NL1_B of the first epitaxial layer 150_NL1 tends to increase from the first point PT11 and PT21 to the second point PT12 and PT22, it may be said to be symmetrical even if it is not completely identical. However, in the first part 150_A1 of the source/drain region 150, the shape of the lower end 150_NL1_B of the first epitaxial layer 150_NL1 increases from the first point PT11 and PT21 to the second point PT12 and PT22, but if in the second part 150_A2 of the source/drain region 150, the shape of the lower end 150_NL1_B of the first epitaxial layer 150_NL1 decreases from the first point PT11 and PT21 to the second point PT12 and PT22, or in the second part 150_A2 of the source/drain region 150, the shape of the lower end 150_NL1_B of the first epitaxial layer 150_NL1 increases and then decreases again from the first point PT11 and PT21 to the second point PT12 and PT22, it cannot be said to be symmetrical.

In some embodiments, in the first cross-section, that is, as one example, in FIG. 5 and FIG. 6, the thickness T_NL1 of the lower end 150_NL1_B of the first epitaxial layer 150_NL1 has a minimum value T_NL1_MIN in the first point PT11 and PT21, and a value larger than the minimum value T_NL1_MIN in the second point PT12 and PT22.

Here, the thickness T_NL1 of the lower end 150_NL1_B of the first epitaxial layer 150_NL1 means the length in the third direction D3 from the upper surface of the active pattern AP to the upper surface of the lower end 150_NL1_B of the first epitaxial layer 150_NL1.

As an example, in the first cross-section, the thickness T_NL1 of the lower end 150_NL1_B of the first epitaxial layer 150_NL1 may have a minimum value T_NL1_MIN at the first point PT11 and PT21, and a maximum value T_NL1_MAX at the second point PT12 and PT22. Here, the minimum value T_NL1_MIN may be substantially 0.

For example, in the first cross-section, the thickness T_NL1 of the lower end 150_NL1_B of the first epitaxial layer 150_NL1 may increase as it approaches in the second direction D2 from the first point PT11 and PT21 towards the second point PT12 and PT22. For, in the first cross-section, the thickness T_NL1 of the lower end 150_NL1_B of the first epitaxial layer 150_NL1 has the minimum value T_NL1_MIN at the first point PT11 and PT21, and increases as it approaches the second point PT12 and PT22, and may have the maximum value of T_NL1_MAX at the second point PT12 and PT22.

In the first cross-section, in an embodiment a ratio of the thickness T_NL1 of the lower end 150_NL1_B of the first epitaxial layer 150_NL1 at the second point PT12 and PT22 for the thickness T_NL1 of the lower end 150_NL1_B of the first epitaxial layer 150_NL1 at the first point PT11 and PT21 may be 2 or more, for example, 3 or more, 4 or more, 5 or more, 6 or more, 7 or more, 8 or more, 9 or more, 10 or more, 20 or more, 30 or more, 40 or more, 50 or more, 60 or more, 70 or more. In the first cross-section, in an embodiment a ratio of the thickness T_NL1 of the lower end 150_NL1_B of the first epitaxial layer 150_NL1 at the second point PT12 and PT22 for the thickness T_NL1 of the lower end 150_NL1_B of the first epitaxial layer 150_NL1 at the first point PT11 and PT21 may be 80 or more, 90 or more, or 100 or more, and may be 100 or less, 90 or less, 80 or less, 70 or less, 60 or less, 50 or less, 40 or less, 30 or less, 20 or less, 10 or less, 9 or less, 8 or less, 7 or less, 6 or less, 5 or less, 4 or less, or 3 or less.

As described above, in the semiconductor device according to some embodiments, the source/drain region 150 is formed and then the barrier rib 200 is formed. In the absence of the barrier rib 200, when the source/drain region 150 is formed, the first epitaxial layer 150_NL1 is formed to have a shape in which the lower end 150_NL1_B is convex upwardly in the third direction D3 in the first cross-section, and forms, for example, a bell shape. Afterwards, by forming the barrier rib 200 and dividing the source/drain region 150 into, for example, the first part 150_A1 and the second part 150_A2, in the first cross-section, the thickness T_NL1 of the lower end 150_NL1_B of the first epitaxial layer 150_NL1 may have the minimum value T_NL1_MIN at the first point PT11 and PT21, increases as it approaches the second point PT12 and PT22, and may have the maximum value T_NL1_MAX at the second point PT12 and PT22.

On the other hand, as shown in FIG. 7, in a comparative embodiment in which the barrier rib 200 is formed first, since the first epitaxial layer 150_NL1 is formed separately in each region divided by the barrier rib 200, the first epitaxial layer 150_NL1 of each of the first part 150_A1 and the second part 150_A2 of the source/drain region 150 is formed to have a shape in which the lower end 150_NL1_B is convex upwardly towards the third direction D3, and forms, for example, a bell shape. Therefore, in this comparative embodiment, the thickness T_NL1 of the lower end 150_NL1_B of the first epitaxial layer 150_NL1 has the minimum value T_NL1_MIN at the first point PT11 and PT21, increases as it approaches the second point PT12 and PT22, and then has the maximum value T_NL1_MAX, and then again starts to decrease and has the minimum value T_NL1_MIN again at the second point PT12 and PT22.

In some embodiments, in the first cross-section, for example, as shown in FIG. 5 and FIG. 6, the lower end 150_NL1_B of the first epitaxial layer 150_NL1 is in surface-contact with the barrier rib 200. In addition, the sidewall part 150_NL1_S of the first epitaxial layer 150_NL1 may be in surface-contact with the barrier rib 200. For example, the lower end 150_NL1_B and the sidewall part 150_NL1_S of the first epitaxial layer 150_NL1 have a contact area with the barrier rib 200 and do not make a point contact or a line contact. For example, the surface-contact of the lower end 150_NL1_B of the first epitaxial layer 150_NL1 and/or the sidewall part 150_NL1_S of the first epitaxial layer 150_NL1 with the barrier rib 200 may be a planar contact.

As described above, in the semiconductor device according to some embodiments, the source/drain region is formed and then the barrier rib 200 is formed. In the absence of the barrier rib 200, when the source/drain region 150 is formed, the first epitaxial layer 150_NL1 is formed to have a shape in which the lower end 150_NL1_B is convex upwardly in the third direction D3 in the first cross-section, for example, a bell shape. Next, when dividing the source/drain region 150, for example, into the first part 150_A1 and the second part 150_A2 by forming the barrier rib 200, the lower end 150_NL1_B and the sidewall part 150_NL1_S of the first epitaxial layer 150_NL1 are in surface-contact with the barrier rib 200.

On the other hand, as shown in FIG. 7, in a comparative embodiment in which the barrier rib 200 is formed first, since the first epitaxial layer 150_NL1 is formed separately in each region divided by the barrier rib 200, the first epitaxial layer 150_NL1 of each of the first part 150_A1 and the second part 150_A2 of the source/drain region 150 is formed to have a shape in which the lower end 150_NL1_B is convex upwardly in the third direction D3, for example, a bell shape. Therefore, in this case, the lower end 150_NL1_B and the sidewall part 150_NL1_S of the first epitaxial layer 150_NL1 do not contact the barrier rib 200, or even if they are in contact with the barrier rib 200, they are in contact with a dot or a line.

In an embodiment, if the source/drain region 150 further includes the third epitaxial layer 150_NL3 or the fourth epitaxial layer 150_NL4, some parts 150_A1 and 150_A2 of the source/drain region 150 may not have the axes AXIS1 and AXIS2 on which the shape of the lower end 150_NL3_B and 150_NL4_B of the third epitaxial layer 150_NL3 and the fourth epitaxial layer 150_NL4 is symmetrical in the first cross-section.

On the other hand, in the first cross-section, the first part 150_A1 and the second part 150_A2 of the source/drain region 150 may have the shape in which the thickness profile of the lower end 150_NL3_B and 150_NL4_B of the third epitaxial layer 150_NL3 and the fourth epitaxial layer 150_NL4) is symmetrical around the barrier rib 200.

Also, in the first cross-section, that is, as one example shown in FIG. 5 and FIG. 6, the thickness T_NL3 and T_NL4 of the lower end 150_NL3_B and 150_NL4_B of the third epitaxial layer 150_NL3 and the fourth epitaxial layer 150_NL4 may have the minimum value T_NL3_MIN and T_NL4_MIN at the first point PT11 and PT21, and a value larger than the minimum value T_NL3_MIN and T_NL4_MIN (e.g., the maximum values T_NL3_MAX, T_NL4_MAX) at the second point PT12 and PT22.

Here, the thickness T_NL3 of the lower end 150_NL3_B of the third epitaxial layer 150_NL3 means the length in the third direction D3 from the upper surface of the lower end 150_NL1_B of the first epitaxial layer 150_NL1 to the upper surface of the lower end 150_NL3_B of the third epitaxial layer 150_NL3. In addition, the thickness T_NL4 of the lower end 150_NL4_B of the fourth epitaxial layer 150_NL4 means the length in the third direction D3 from the upper surface of the lower end 150_NL3_B of the third epitaxial layer 150_NL3 to the upper surface of the lower end 150_NL4_B of the fourth epitaxial layer 150_NL4.

As an example, in an embodiment, in the first cross-section, the thickness T_NL3 and T_NL4 of the lower end 150_NL3_B and 150_NL4_B of the third epitaxial layer 150_NL3 and the fourth epitaxial layer 150_NL4 may have a minimum value T_NL3_MIN and T_NL4_MIN at the first point PT11 and PT21 and a maximum value T_NL3_MAX and T_NL4_MAX at the second point PT12 and PT22. Here, the minimum value T_NL3_MIN and T_NL4_MIN may be substantially 0.

For example, in the first cross-section, the thickness T_NL3 and T_NL4 of the lower end 150_NL3_B and 150_NL4_B of the third epitaxial layer 150_NL3 and the fourth epitaxial layer 150_NL4 may increase from the first point PT11 and PT21 towards the second point PT12 and PT22 in the second direction D2. For example, in the first cross-section, the thickness T_NL3 and T_NL4 of the lower end 150_NL3_B and 150_NL4_B of the third epitaxial layer 150_NL3 and the fourth epitaxial layer 150_NL4 may have a minimum value T_NL3_MIN and T_NL4_MIN at the first point PT11 and PT21 and increase as it approaches the second points PT12 and PT22, and has a maximum value T_NL3_MAX and T_NL4_MAX at the second points PT12 and PT22.

In an embodiment, in the first cross-section, the ratio of the thickness T_NL3 of the lower end 150_NL3_B of the third epitaxial layer 150_NL3 at the second point PT12 and PT22 to the thickness T_NL3 of the lower end 150_NL3_B of the third epitaxial layer 150_NL3 at the first point PT11 and PT21 may be 2 or more, for example, 3 or more, 4 or more, 5 or more, 6 or more, 7 or more, 8 or more, 9 or more, 10 or more, 20 or more, 30 or more, 40 or more, 50 or more, 60 or more, 70 or more. The ratio of the thickness T_NL3 of the lower end 150_NL3_B of the third epitaxial layer 150_NL3 at the second point PT12 and PT22 to the thickness T_NL3 of the lower end 150_NL3_B of the third epitaxial layer 150_NL3 at the first point PT11 and PT21 may be 80 or more, 90 or more, or 100 or more, and may be 100 or less, 90 or less, 80 or less, 70 or less, 60 or less, 50 or less, 40 or less, 30 or less, 20 or less, 10 or less, 9 or less, 8 or less, 7 or less, 6 or less, 5 or less, 4 or less, or 3 or less.

Also, in an embodiment, in the first cross-section, the ratio of the thickness T_NL4 of the lower end 150_NL4_B of the fourth epitaxial layer 150_NL4 at the second point PT12 and PT22 to the thickness T_NL4 of the lower end 150_NL4_B of the fourth epitaxial layer 150_NL4 at the first point PT11 and PT21 may be 2 or more, for example, 3 or more, 4 or more, 5 or more, 6 or more, 7 or more, 8 or more, 9 or more, 10 or more, 20 or more, 30 or more, 40 or more, 50 or more, 60 or more, 70 or more. The ratio of the thickness T_NL4 of the lower end 150_NL4_B of the fourth epitaxial layer 150_NL4 at the second point PT12 and PT22 to the thickness T_NL4 of the lower end 150_NL4_B of the fourth epitaxial layer 150_NL4 at the first point PT11 and PT21 may be 80 or more, 90 or more, or 100 or more, and may be 100 or less, 90 or less, 80 or less, 70 or less, 60 or less, 50 or less, 40 or less, 30 or less, 20 or less, 10 or less, 9 or less, 8 or less, 7 or less, 6 or less, 5 or less, 4 or less, or 3 or less.

For example, in the first cross-section, for example, in FIG. 5 and FIG. 6, the lower end 150_NL4_B of the third epitaxial layer 150_NL3 and the fourth epitaxial layer 150_NL4 may be in surface-contact with the barrier rib 200. In addition, the sidewall part 150_NL3_S and 150_NL4_S of the third epitaxial layer 150_NL3 and the fourth epitaxial layer 150_NL4 may be in surface-contact with the barrier rib 200. For example, the lower end 150_NL3_B and 150_NL4_B and the sidewall part 150_NL3_S and 150_NL4_S of the third epitaxial layer 150_NL3 and the fourth epitaxial layer 150_NL4 may have a contact area with the barrier rib 200, and may be not in point-contact or line-contact.

The semiconductor device may further include an interlayer insulating layer 190. The interlayer insulating layer 190 may be positioned on (e.g., disposed thereon) the source/drain region 150. In an embodiment, the interlayer insulating layer 190 may not cover the upper surface of the gate pattern GS. The interlayer insulating layer 190 may be positioned between the sides (e.g., lateral sides) of the gate pattern GS. The interlayer insulating layer 190 may surround the source/drain region 150.

In an embodiment, the interlayer insulating layer 190 may include, for example, silicon oxide (SiO₂), silicon nitride (SiN), silicon oxynitride (SiON), a low dielectric constant material, or a combination thereof. However, embodiments of the present disclosure are not necessarily limited thereto.

In an embodiment, the semiconductor device may further include a gate capping layer 160. The gate capping layer 160 may be positioned on (e.g., disposed directly thereon in the third direction D3) the gate pattern GS. In an embodiment, the upper surface of the gate capping layer 160 may be positioned on the same plane (e.g., in the third direction D3) as the upper surface of the interlayer insulating layer 190 and the upper surface of the etch stop layer 185. The gate capping layer 160 may be positioned between the sides of the interlayer insulating layer 190 (e.g., in the first direction D1).

In an embodiment, the gate capping layer 160 may include, for example, silicon nitride (SiN), silicon oxynitride (SiON), silicon (Si) carbide nitride (SiCN), silicon carbonate nitride (SiOCN), or a combination thereof. However, embodiments of the present disclosure are not necessarily limited thereto.

In an embodiment, an etch stop layer 185 may be further positioned between the interlayer insulating layer 190 and the source/drain region 150 of the semiconductor device, and between the interlayer insulating layer 190 and the gate spacer 140. In an embodiment, the etch stop layer 185 may be positioned on the side (e.g., lateral side) of the gate spacer 140 and on the upper surface of the source/drain region 150. Additionally, the etch stop layer 185 may surround at least a portion of the source/drain region 150. In an embodiment, the etch stop layer 185 may also be positioned on (e.g., disposed directly on) the side (e.g., a lateral side) of the gate capping layer 160.

In an embodiment, the etch stop layer 185 may include a material having an etch selectivity with respect to the interlayer insulating layer 190. Additionally, the etch stop layer 185 may include a material having an etch selectivity with respect to the source/drain region 150. In an embodiment, the etch stop layer 185 may include, for example, silicon nitride (SiN), silicon oxynitride (SiON), silicon carbonate nitride (SiOCN), silicon boronnitride (SiBN), silicon acid boronnitride (SiOBN), silicon oxycarbide (SiOC), or a combination thereof.

In an embodiment, the semiconductor device may further include an upper insulation layer 195.

The upper insulation layer 195 may be positioned on (e.g., disposed directly thereon in the third direction D3) the upper surface of the interlayer insulating layer 190, the upper surface of the etch stop layer 185, and the upper surface of the gate capping layer 160.

In an embodiment, the semiconductor device according to an embodiment may further include a contact electrode.

The contact electrode may be positioned on (e.g., disposed directly thereon) the gate pattern GS. The contact electrode may be electrically connected to the gate pattern GS by penetrating the upper insulation layer 195 and the gate capping layer 160. As an example, the lower surface of the contact electrode may be surrounded by the gate pattern GS. In an embodiment, the lower surface of the contact electrode may be positioned at a lower level than the upper surface of the gate pattern GS. In an embodiment, the contact electrode may be positioned on one side and/or the other side of the barrier rib 200. As another example, the contact electrode may be positioned on (e.g., disposed directly thereon) the gate pattern GS and the contact electrode may be positioned on (e.g., disposed directly thereon) the barrier rib 200. The lower surface of the contact electrode may be surrounded by the gate pattern GS and the barrier rib 200.

In an embodiment, the contact electrode may include a conductive material. The contact electrode may include, for example, a metal, a metal alloy, a conductive metal nitride, a conductive metal carbide, a conductive metal oxide, a conductive metal nitride, a two-dimensional material (2D material), or a combination thereof. However, embodiments of the present disclosure are not necessarily limited thereto.

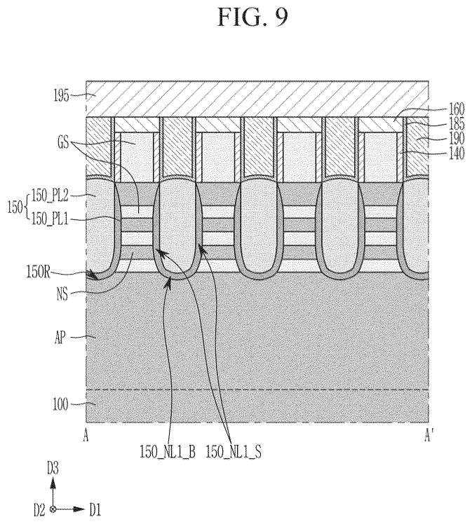

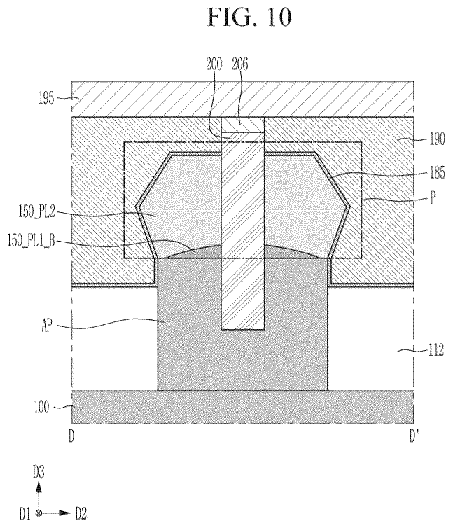

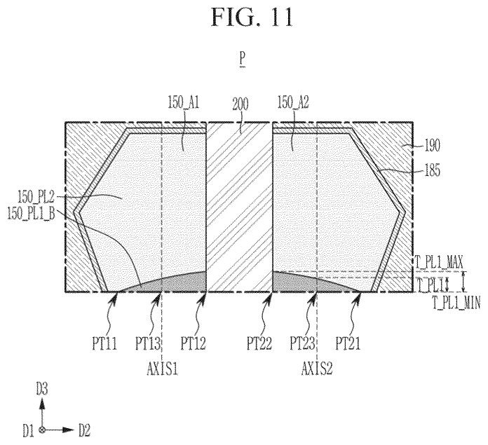

A semiconductor device according to some embodiments is described with reference to FIG. 9 to FIG. 11,

FIG. 9 to FIG. 11 show a semiconductor device according to some embodiments, and are cross-sectional views corresponding to FIG. 2, FIG. 5, and FIG. 6, respectively.

Since embodiments shown in FIG. 9 to FIG. 11 includes many parts that are the same as embodiments shown in FIG. 1 and FIG. 8, a repeated description thereof may be omitted and differences are mainly explained for economy of description.

FIG. 1 to FIG. 8 show that the third epitaxial layer 150_NL3 and the fourth epitaxial layer 150_NL4 are positioned between the first epitaxial layer 150_NL1 and the second epitaxial layer 150_NL2, and a fifth epitaxial layer 150_NL5 is positioned on the second epitaxial layer 150_NL2. As an example, this shape may represent a source/drain structure of a PMOS transistor.

FIG. 9 to FIG. 11 show embodiments in which the source/drain region 150 does not further include the third epitaxial layer, the fourth epitaxial layer, and the fifth epitaxial layer, and solely includes the first epitaxial layer 150_PL1 and the second epitaxial layer 150_PL2. This shape may represent the source/drain structure of the NMOS transistor.

However, in this embodiment as well, some parts, such as first and second parts 150_A1 and 150_A2 of the source/drain region 150 do not have axes AXIS1 and AXIS2 on which the shape of the lower end 150_PL1_B of the first epitaxial layer 150_PL1 is symmetrical in the first cross-section, and the first part 150_A1 and the second part 150_A2 of the source/drain region 150 may have the shape in which the thickness profile of the lower end 150_PL1_B of the first epitaxial layer 150_PL1 is symmetrical around the barrier rib 200.

Additionally, in the first cross-section, the thickness T_PL1 of the lower end 150_PL1_B of the first epitaxial layer 150_PL1 may increase from the first point PT11 and PT21 towards the second point PT12 and PT22 in the second direction D2. For example, in the first cross-section, the thickness T_PL1 of the lower end 150_PL1_B of the first epitaxial layer 150_PL1 may have a minimum value T_PL1_MIN at the first point PT11 and PT21 and increase as it approaches the second point PT12 and PT22. PT12 and PT22, and has a maximum value T_PL1_MAX at the second point PT12 and PT22.

Additionally, in the first cross-section, the lower end 150_PL1_B of the first epitaxial layer 150_PL1 may be in surface-contact with the barrier rib 200. The sidewall part 150_PL1_S of the first epitaxial layer 150_PL1 may be in surface-contact with the barrier rib 200.

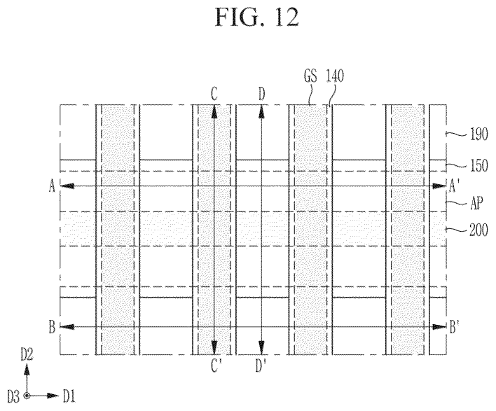

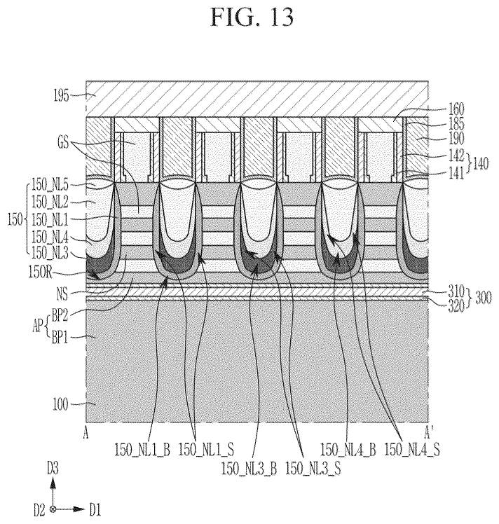

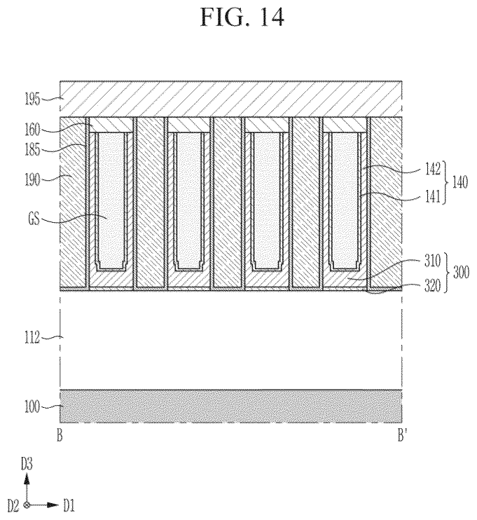

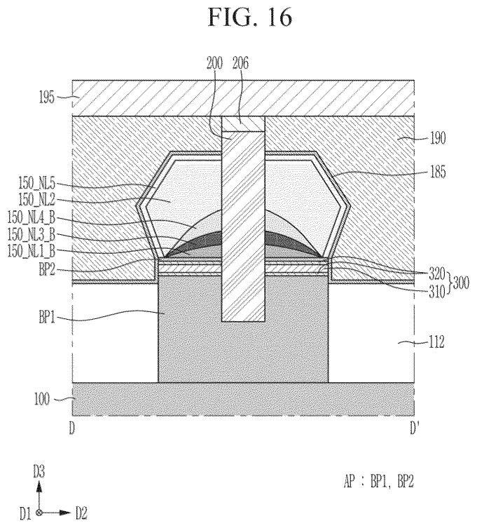

Next, a semiconductor device according to some embodiments is described with reference to FIG. 12 to FIG. 16.

FIG. 12 to FIG. 16 show a semiconductor device according to several embodiments, and are cross-sectional views corresponding to FIG. 1 to FIG. 5 respectively.

Since the embodiment shown in FIG. 12 to FIG. 16 includes many parts that are the same as embodiments shown in FIG. 1 to FIG. 5, a repeated description thereof may be omitted and the differences are mainly explained for economy of description.

FIG. 12 to FIG. 16 show embodiments further including a protection layer 300.

In an embodiment, the active pattern AP may include a first lower pattern BP1 and a second lower pattern BP2. The first lower pattern BP1 may be positioned on (e.g., disposed directly thereon) the substrate 100. The second lower pattern BP2 may be positioned above the first lower pattern BP1 (e.g., in the third direction D3). The first lower pattern BPI and the second lower pattern BP2 may protrude from the substrate 100 (e.g., in the third direction D3). The first lower pattern BP1 and the second lower pattern BP2 may extend longitudinally in the first direction D1. In an embodiment, the first lower pattern BPI and the second lower pattern BP2 may be separated in the third direction D3 by the protection layer 300. For example, the protection layer 300 may be positioned between the first lower pattern BP1 and the second lower pattern BP2 (e.g., in the third direction D3).

In an embodiment, the gate spacer 140 may include a first gate spacer 141 and a second gate spacer 142. The first gate spacer 141 may be positioned on (e.g., disposed directly on) the side (e.g., a lateral side) of the gate pattern GS. The first gate spacer 141 may be positioned between (e.g., directly therebetween) the gate pattern GS and the second gate spacer 142 (e.g., in the first direction D1). The second gate spacer 142 may be positioned on (e.g., disposed directly thereon) the side (e.g., a lateral side) of the first gate spacer 141. The second gate spacer 142 may be positioned between the first gate spacer 141 and the interlayer insulating layer 190 (e.g., in the first direction D1).

In an embodiment, the gate spacer 140 may include the same material as the protection layer 300, which will be described later. For example, in an embodiment the first gate spacer 141 may include the same material as the protection liner 320, and the second gate spacer 142 may include the same material as the protection insulation layer 310. For example, in an embodiment the first gate spacer 141 may include silicon nitride (SiN), and the second gate spacer 142 may include silicon carbonate nitride (SiOCN). However, embodiments of the present disclosure are not necessarily limited thereto. For example, in an embodiment, the first gate spacer 141 and the second gate spacer 142 may respectively include silicon nitride (SiN), silicon oxynitride (SiON), silicon oxide (SiO₂), silicon carbonate nitride (SiOCN), silicon boronnitride (SiBN), and silicon acid boronnitride (SiOBN), silicon oxycarbide (SiOC), or a combination thereof.

The protection layer 300 may be positioned on (e.g., disposed directly thereon) the field insulation layer 112, and the protection layer 300 may extend longitudinally in the first direction D1. The protection layer 300 may be positioned between the first lower pattern BP1 and the second lower pattern BP2 and between the gate pattern GS and the field insulation layer 112 (e.g., in the third direction D3).

In an embodiment, the protection layer 300 may be positioned within a recess 300R extending in the second direction D2. The protection layer 300 may filled the recess 300R. The inner surface of the recess 300R may be defined by the insulation pattern. The lower surface of the recess 300R may be defined as the upper surface of the first lower pattern BP1 and the upper surface of the field insulation layer 112. The upper surface of the recess 300R may be defined as the lower surface of the second lower pattern BP2 and the lower surface of the gate pattern GS.

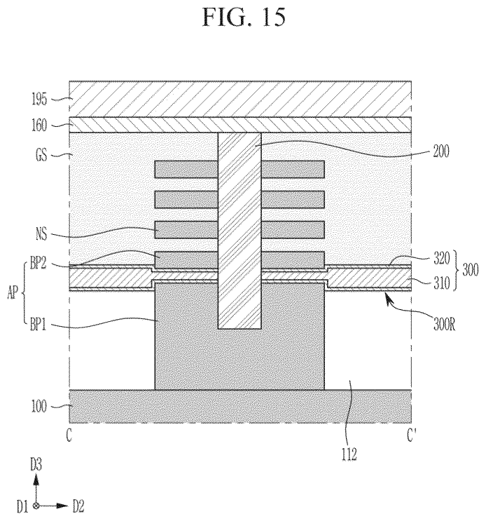

In an embodiment as shown in FIG. 15, the recess 300R may include a step with a different level (e.g., in the third direction D3). For example, in an embodiment, the lower surface portion of the recess 300R defined by the first lower pattern BP1 may be positioned at a higher level (e.g., in the third direction D3) than the lower surface of the recess 300R defined by the field insulation layer 112. Additionally, the upper surface part of the recess 300R defined by the second lower pattern BP2 may be positioned at a lower level (e.g., in the third direction D3) than the upper surface of the recess 300R defined by the gate pattern GS.

Accordingly, the thickness of the portion of the protection layer 300 positioned between the first lower pattern BP1 and the second lower pattern BP2 (e.g., in the third direction D3) may be less than the thickness of the portion of the protection layer 300 positioned between the field insulation layer 112 and the gate pattern GS (e.g., in the third direction D3). Therefore, the gap between the second lower pattern BP2 and the first lower pattern BP1 may be less than the gap between the gate pattern GS and field insulation layer 112.

However, embodiments of the present disclosure are not necessarily limited thereto. For example, in an embodiment the thickness of the portion of the protection layer 300 positioned between the first lower pattern BP1 and the second lower pattern BP2 may be substantially equivalent to the thickness of the portion of the protection layer 300 positioned between the field insulation layer 112 and the gate pattern GS and the recess 300R may not include a step.

In an embodiment, the protection layer 300 may include a protection insulation layer 310 and a protection liner 320.

The protection insulation layer 310 may be positioned on (e.g., disposed on) the field insulation layer 112. The protection insulation layer 310 may be positioned on (e.g., disposed on) the second lower pattern BP2. The protection insulation layer 310 may be positioned within the recess 300R extending in the second direction D2. The protection insulation layer 310 may fill the recess 300R formed between the first lower pattern BP1 and the second lower pattern BP2 and between the gate pattern GS and the field insulation layer 112. In an embodiment, the protection insulation layer 310 may extend longitudinally in the first direction D1.

In an embodiment, the protection insulation layer 310 may include silicon carbonate nitride (SiOCN). However, embodiments of the present disclosure are not necessarily limited thereto. For example, in an embodiment the protection insulation layer 310 may include silicon oxynitride (SiON), silicon carbonate nitride (SiOCN), silicon boronnitride (SiBN), silicon acid boronnitride (SiOBN), silicon oxycarbide (SiOC), or a combination thereof.

The protection liner 320 may be positioned on (e.g., disposed directly thereon) the protection insulation layer 310 within the recess 300R. For example, the protection liner 320 may be positioned on (e.g., disposed directly thereon) the lower surface, side, and upper surface of the protection insulation layer 310 within the recess 300R. For example, the protection liner 320 may be disposed between the protection insulation layer 310 and the second lower pattern BP2, between the protection insulation layer 310 and the first lower pattern BP1, between the protection insulation layer 310 and the insulation pattern, between the protection insulation layer 310 and the gate pattern GS, and between the protection insulation layer 310 and the field insulation layer 112. In an embodiment, the protection liner 320 may extend in a constant thickness along the profile of the recess 300R. As described above, since the recess 300R may include the step in an embodiment, the protection liner 320 may have a curved part corresponding to the step. In an embodiment, the protection liner 320 may extend longitudinally in the first direction D1.

In an embodiment, the protection liner 320 may include silicon nitride (SiN). However, embodiments of the present disclosure are not necessarily limited thereto.

As the field insulation layer 112 is protected by the protection liner 320 and the protection insulation layer 310, when forming the gate pattern GS, a leakage current that occurs between the gate pattern GS and the first lower pattern BP1, and between the gate pattern GS and the adjacent source/drain region 150 may be reduced. Accordingly, the reliability of the semiconductor device may be increased.

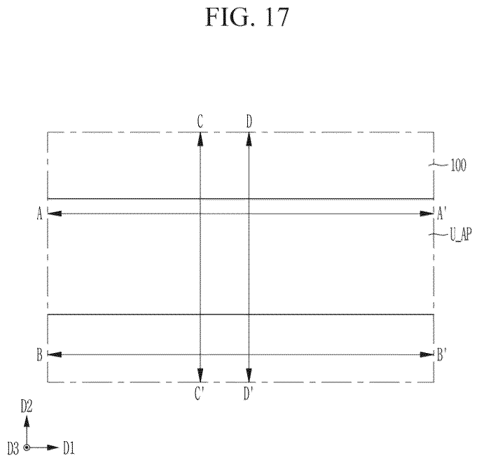

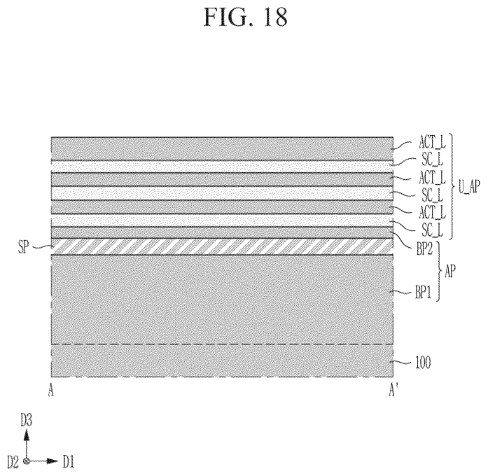

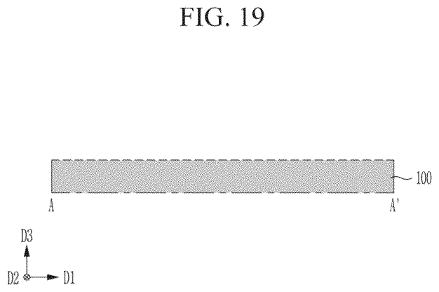

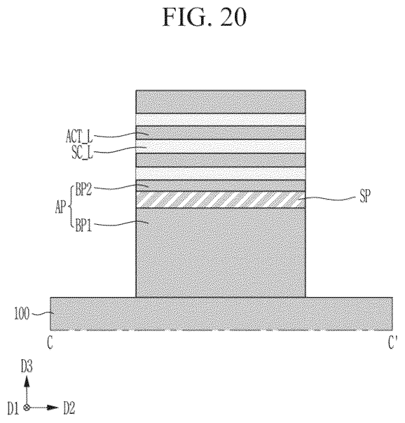

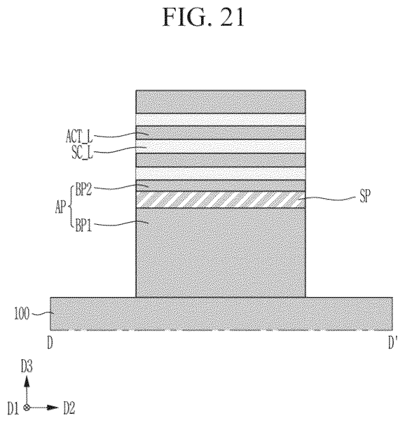

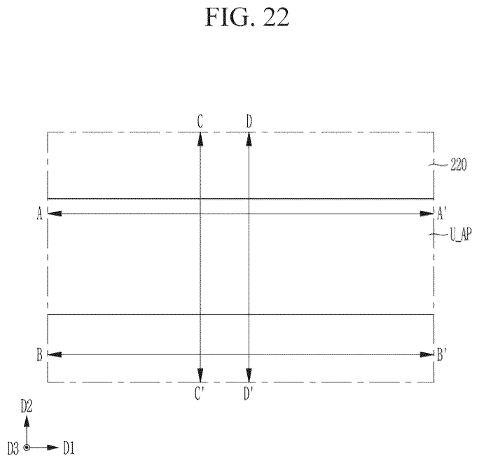

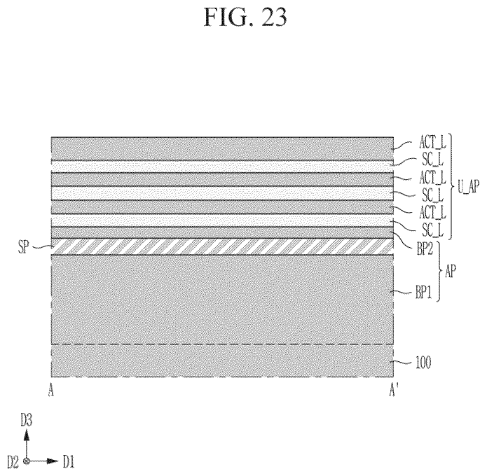

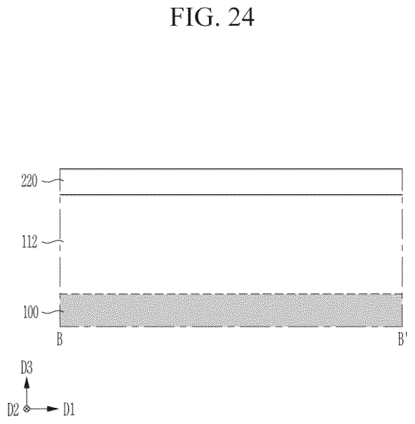

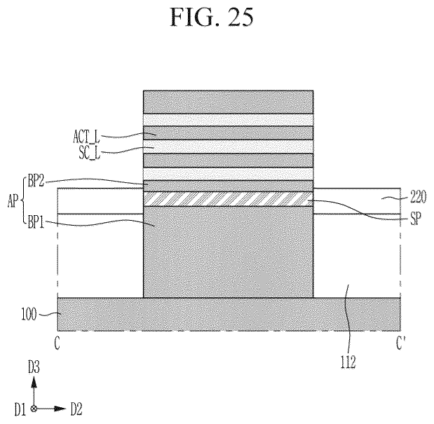

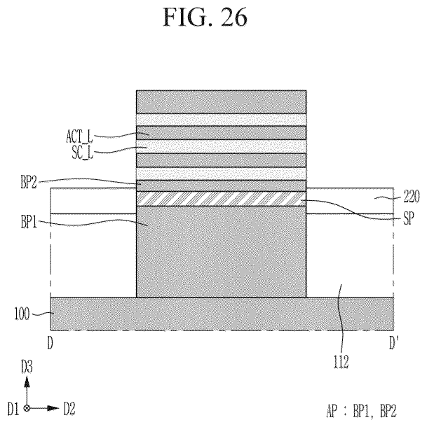

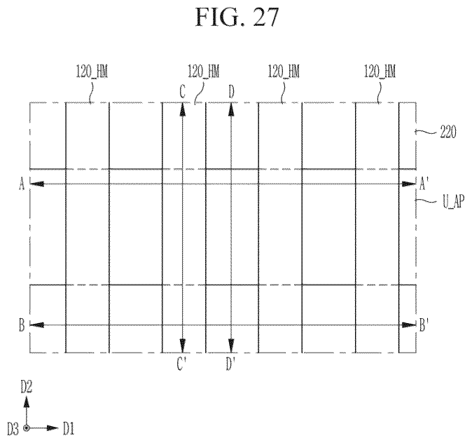

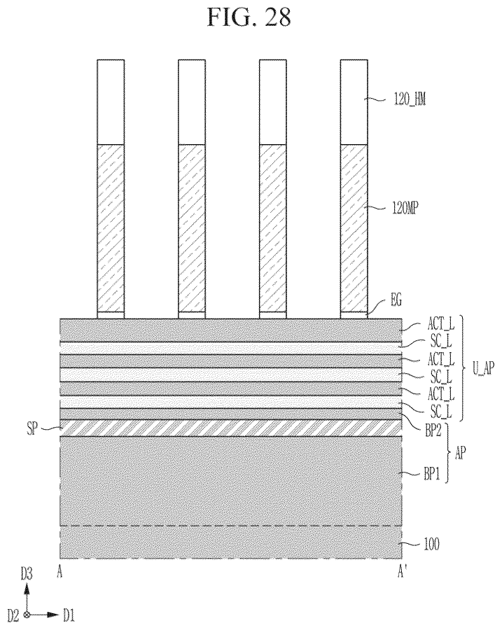

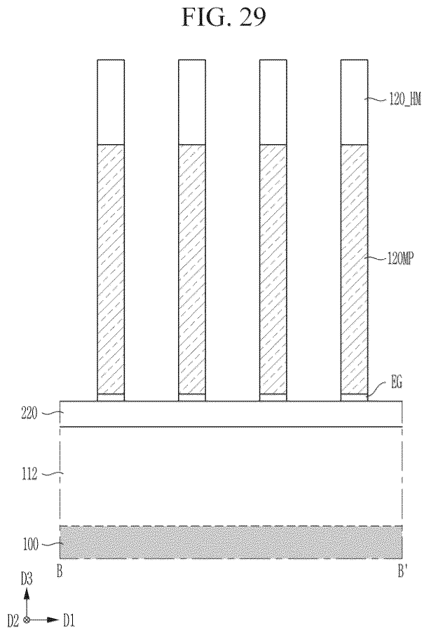

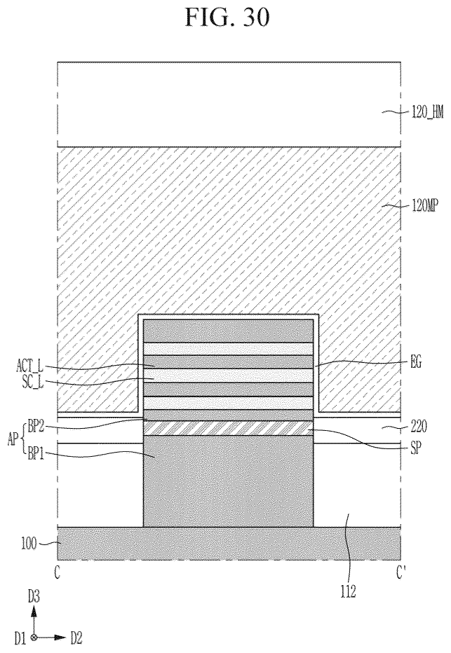

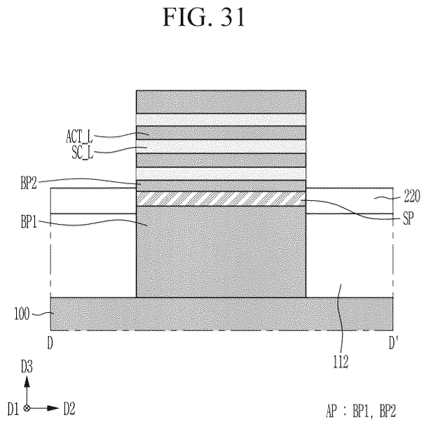

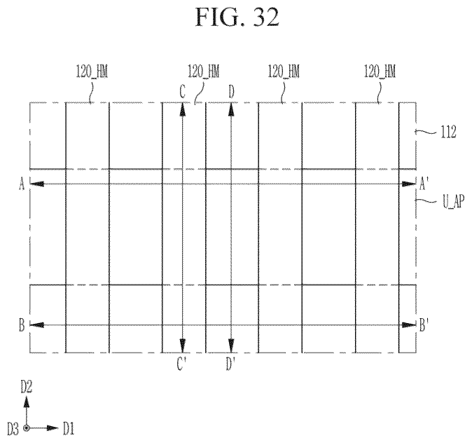

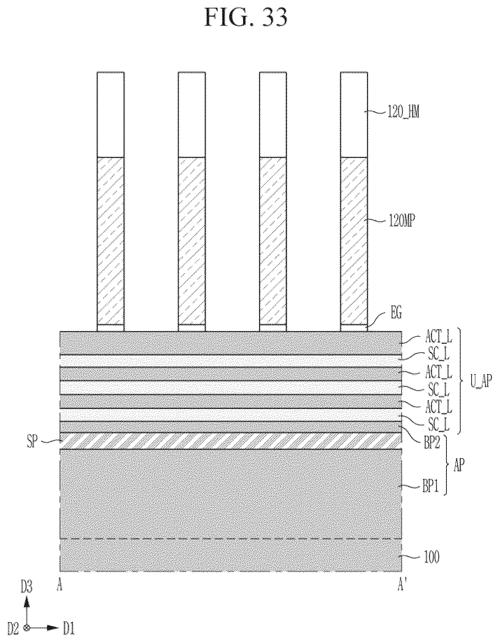

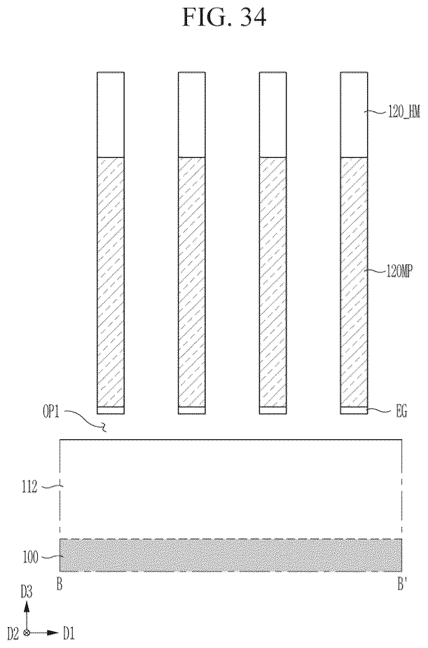

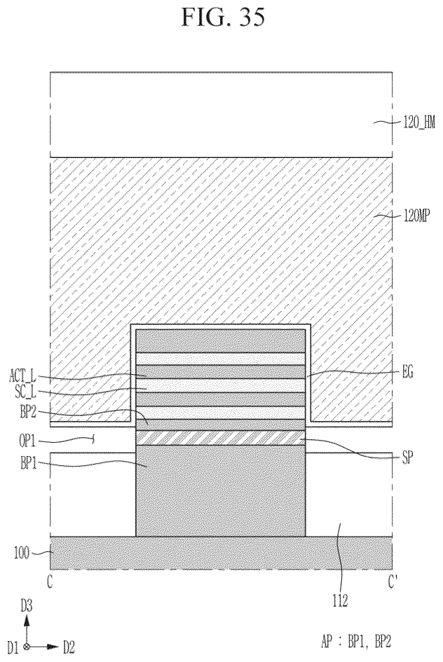

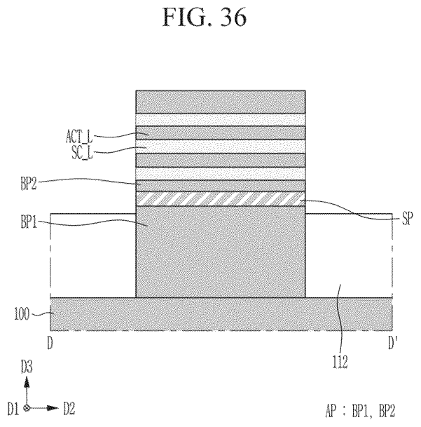

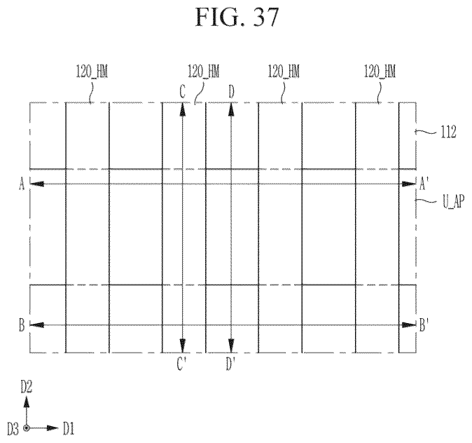

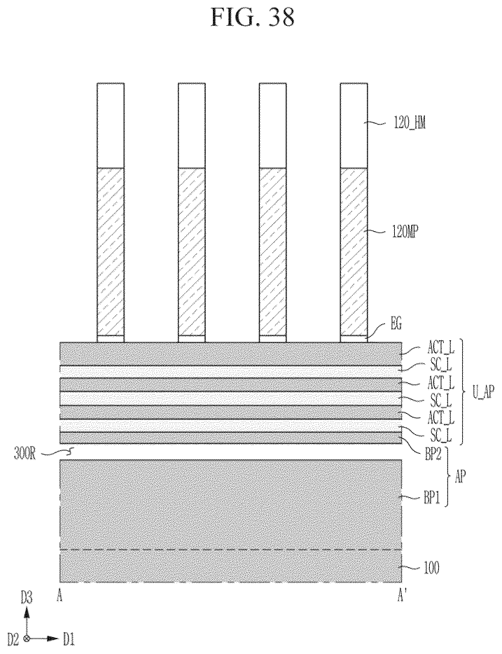

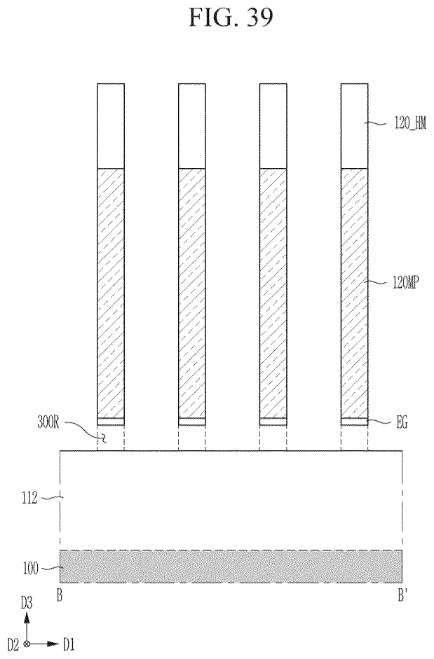

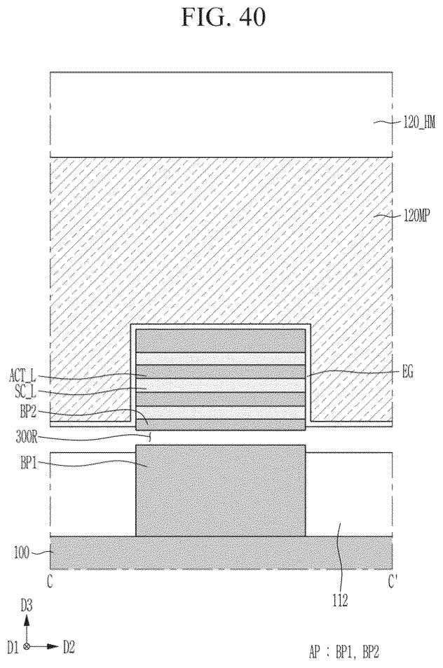

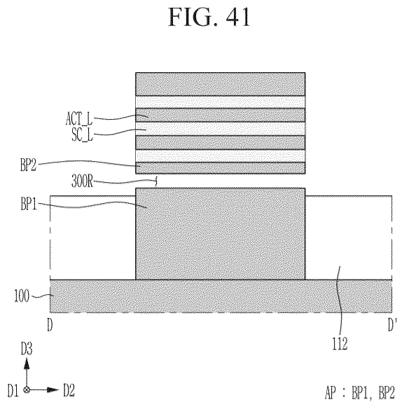

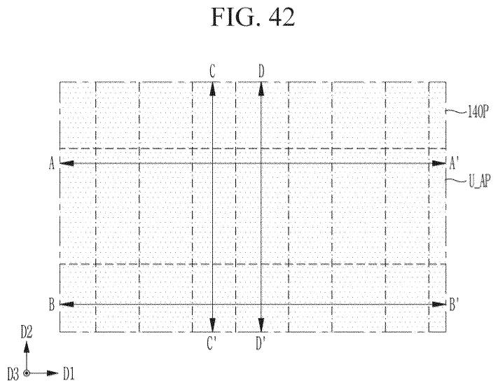

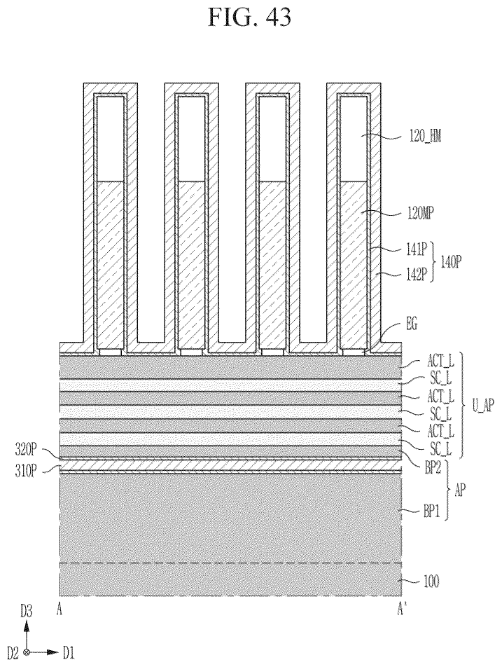

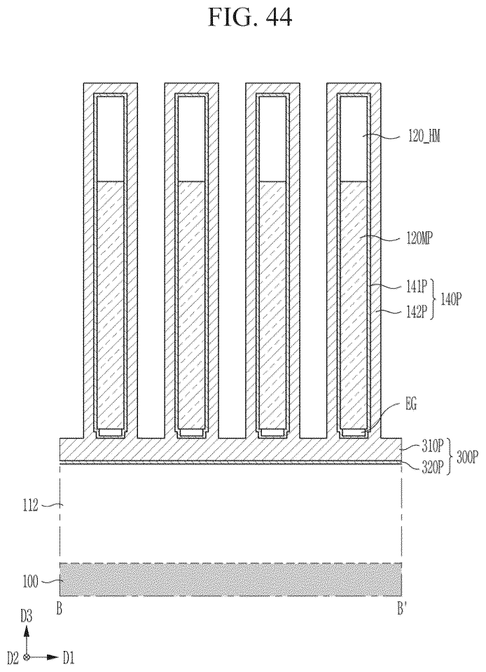

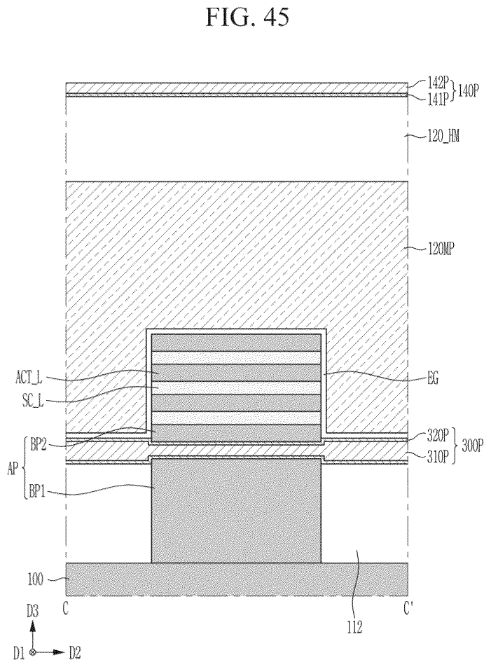

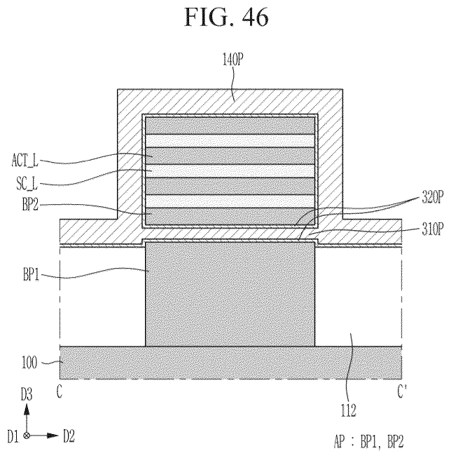

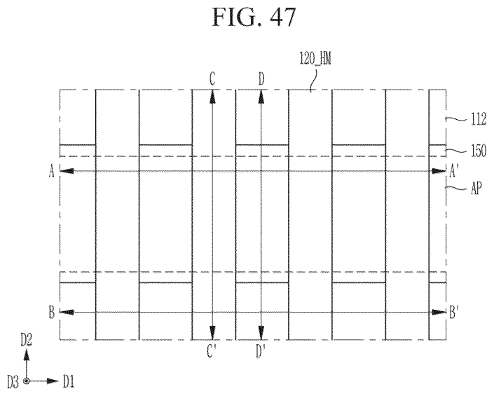

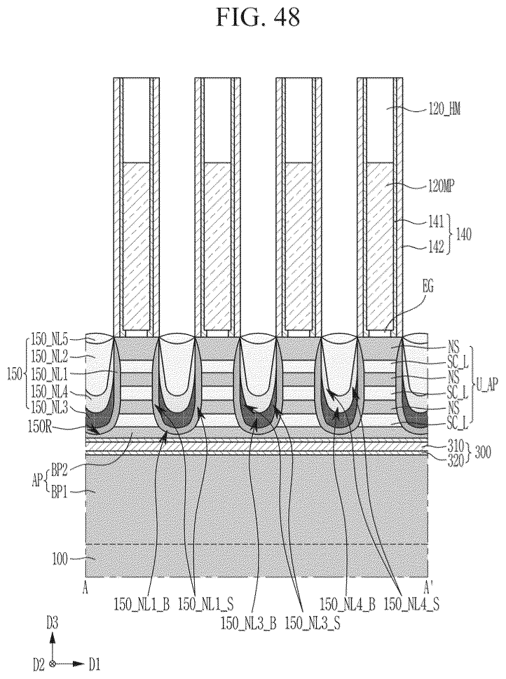

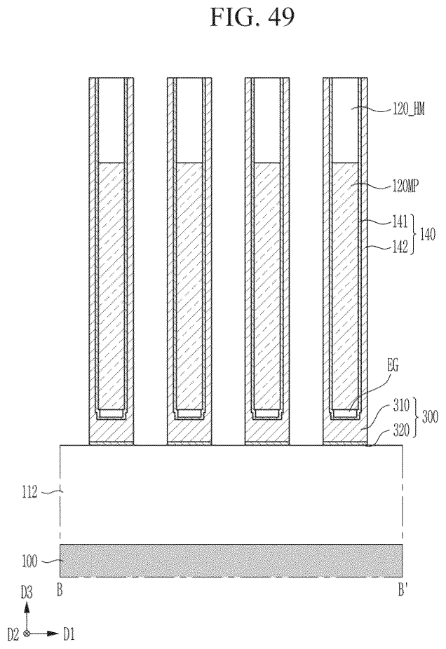

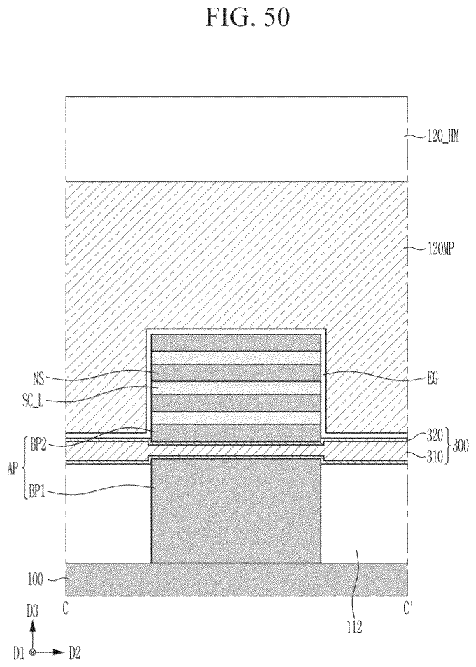

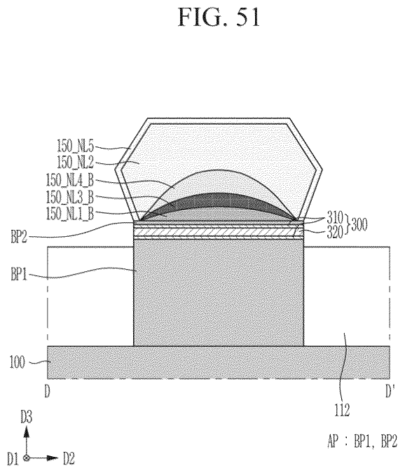

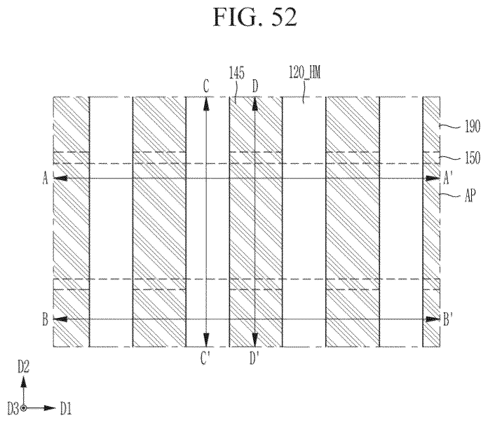

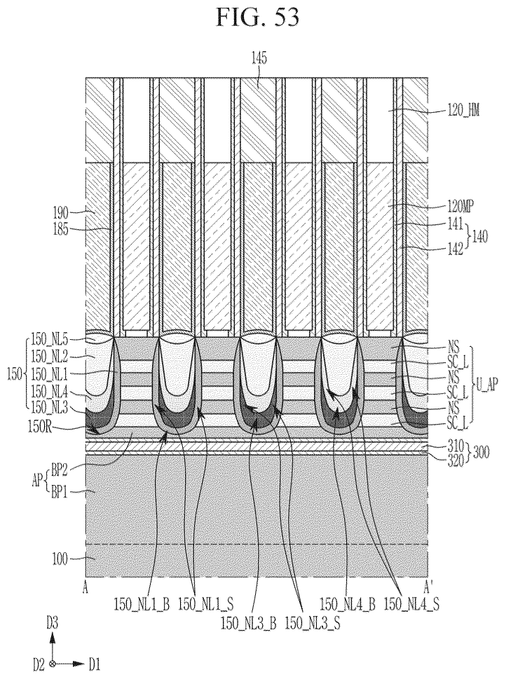

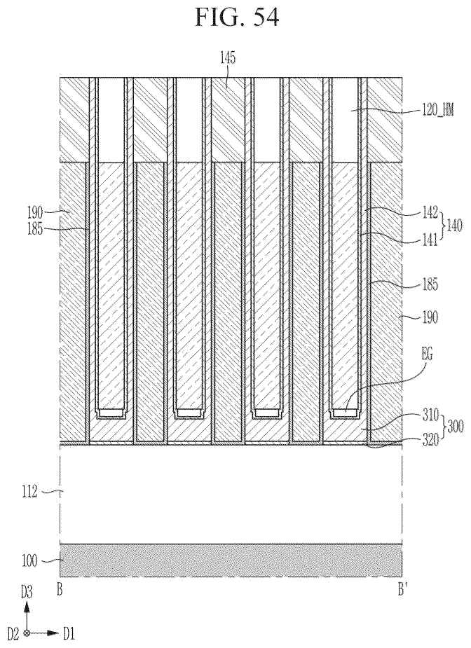

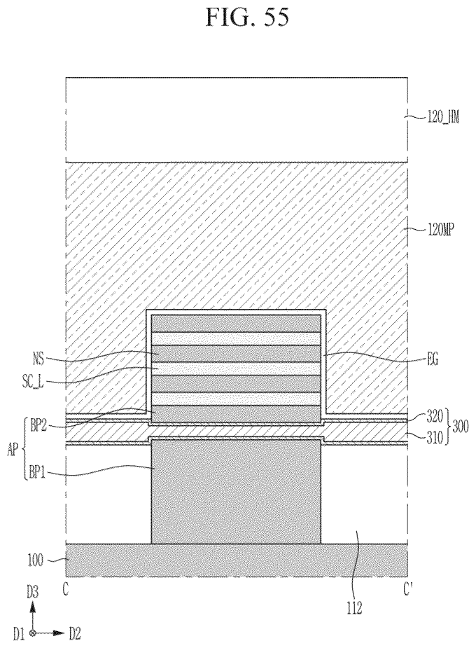

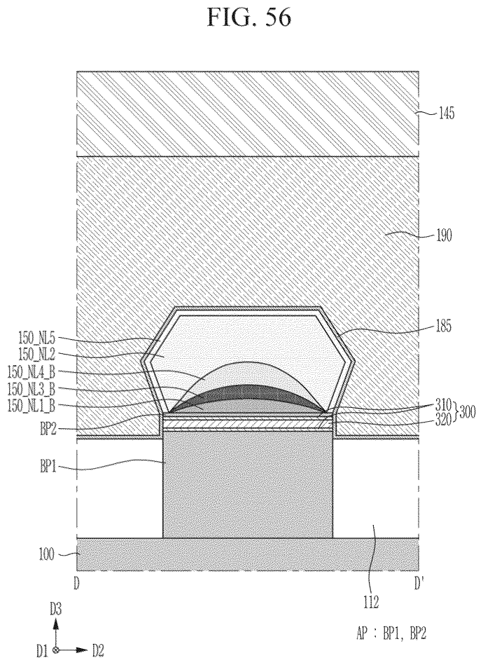

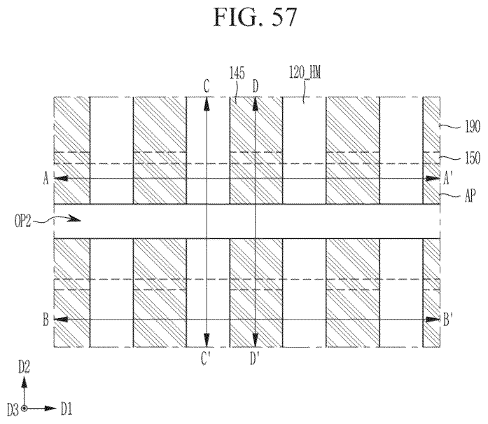

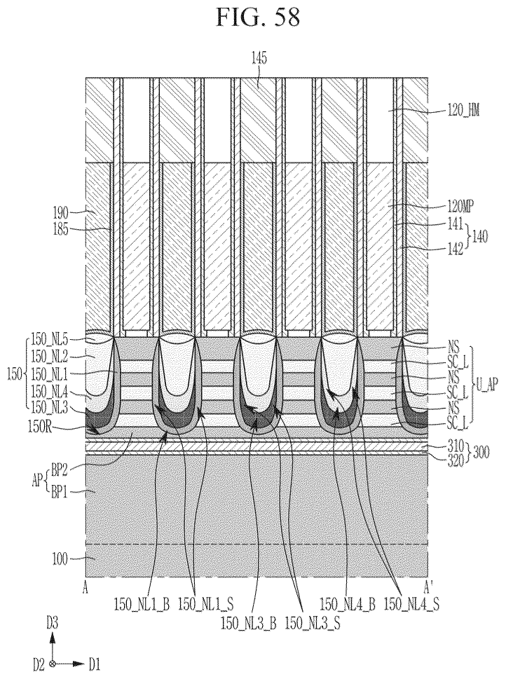

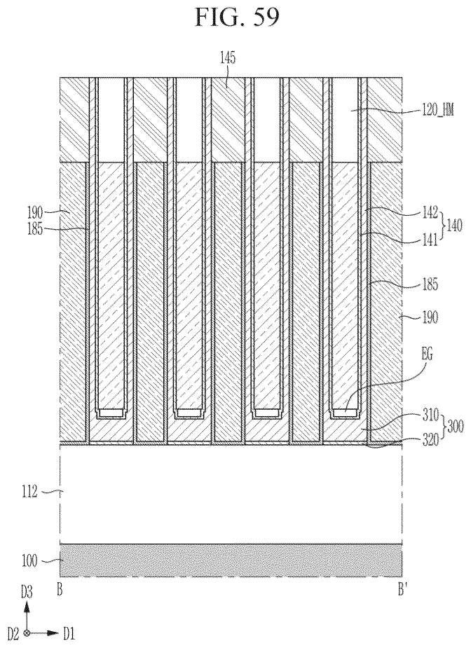

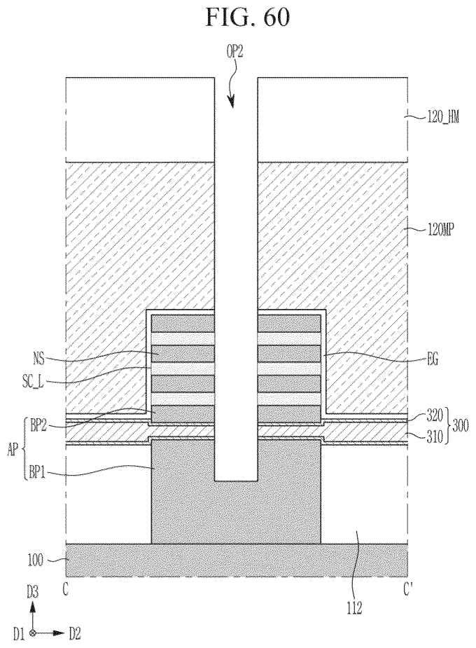

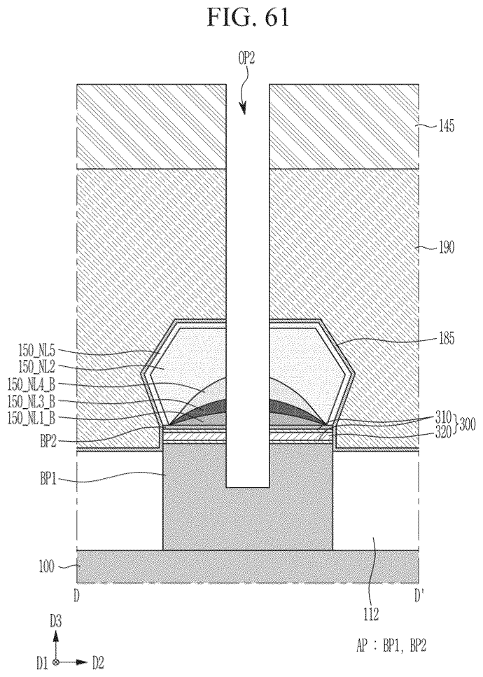

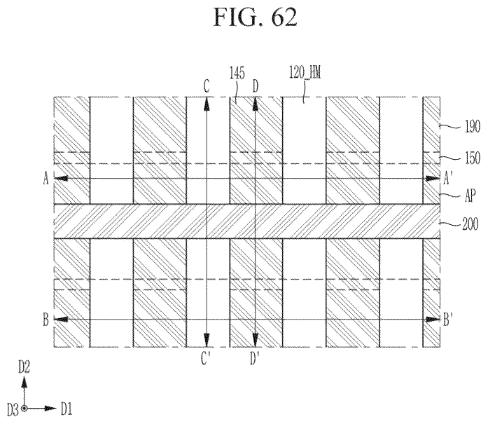

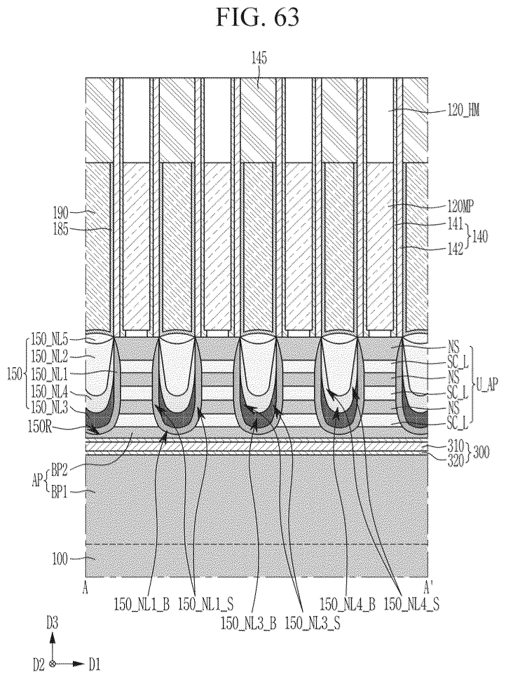

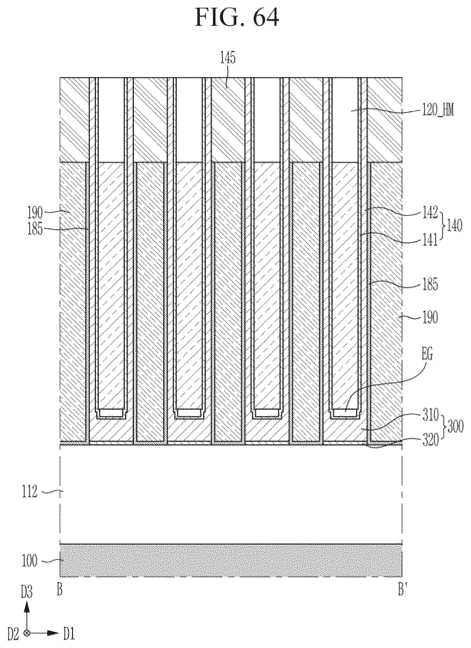

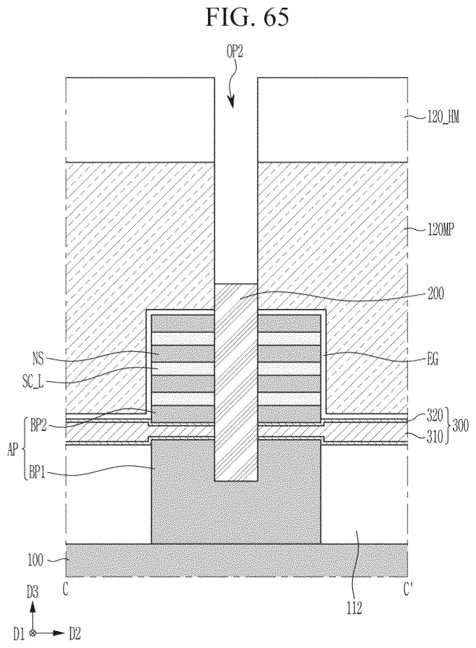

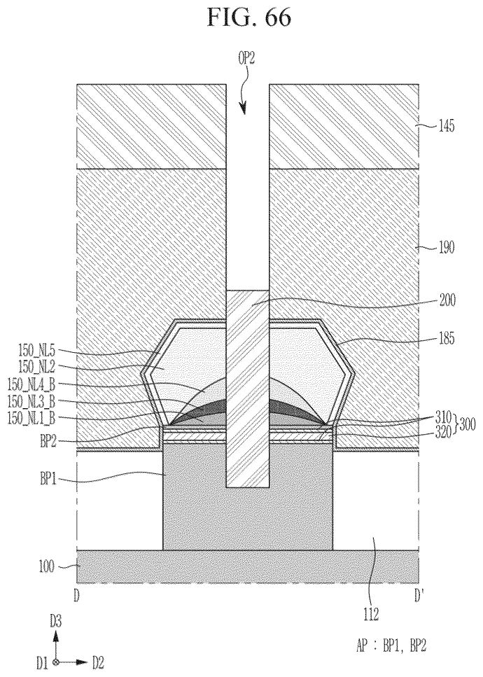

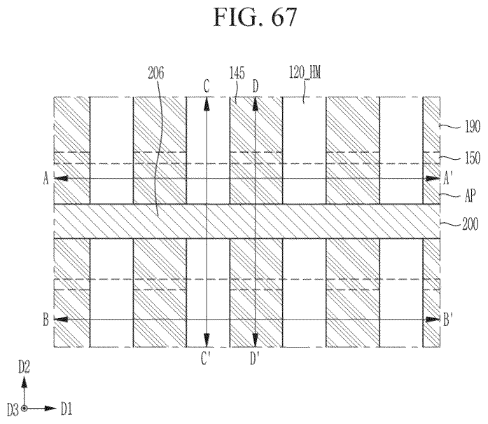

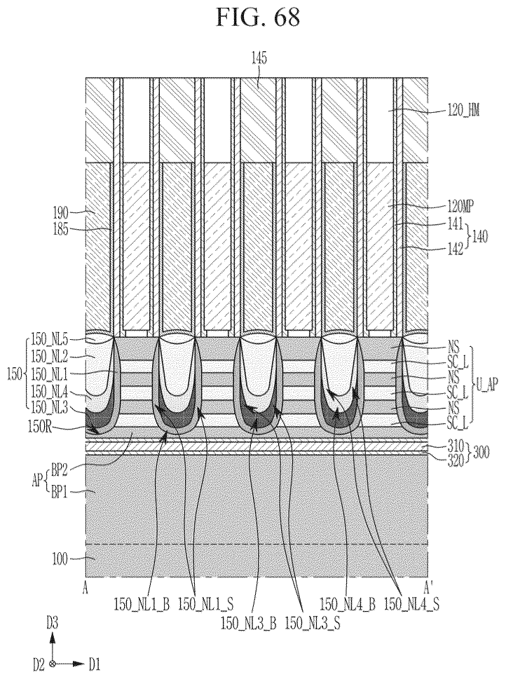

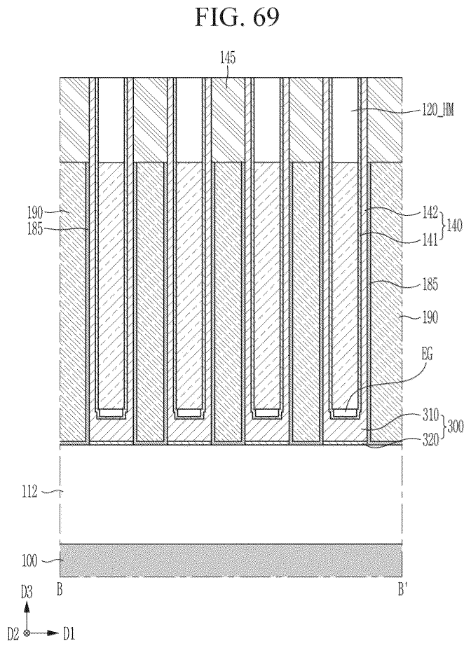

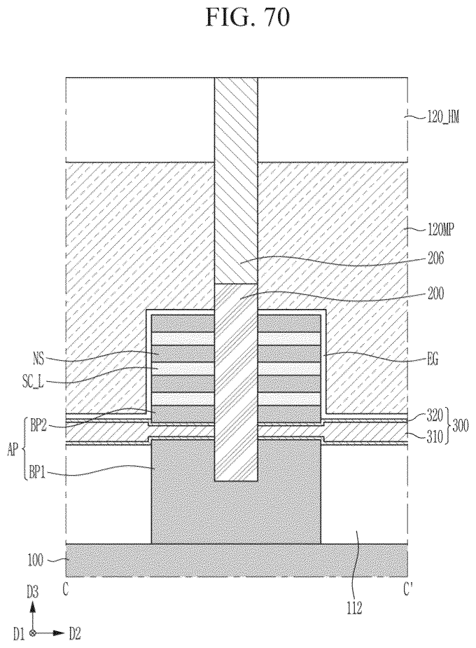

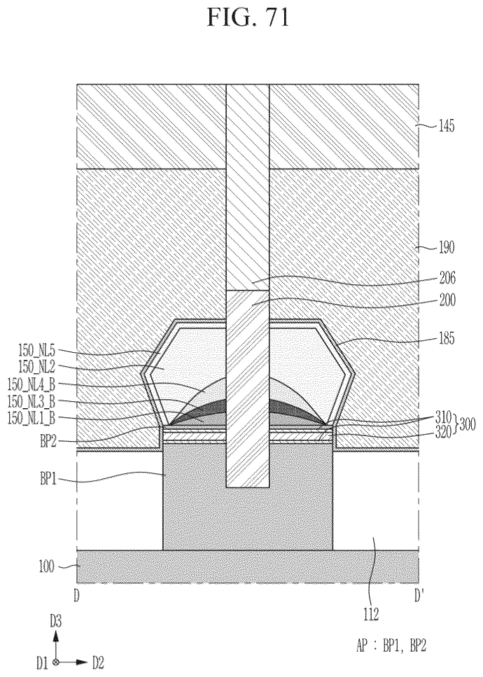

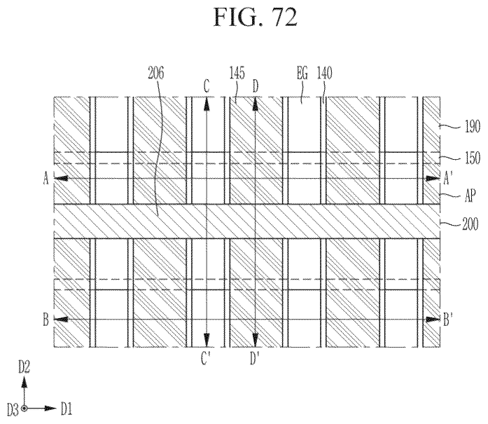

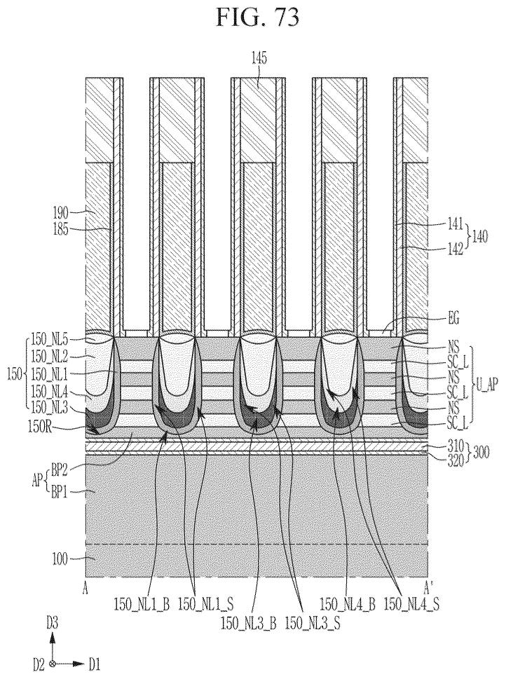

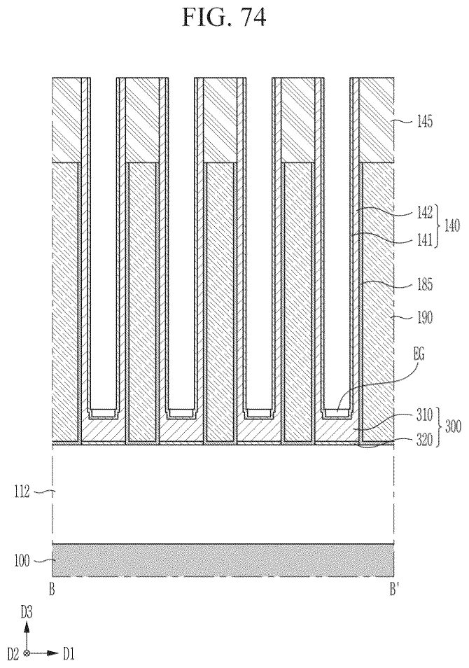

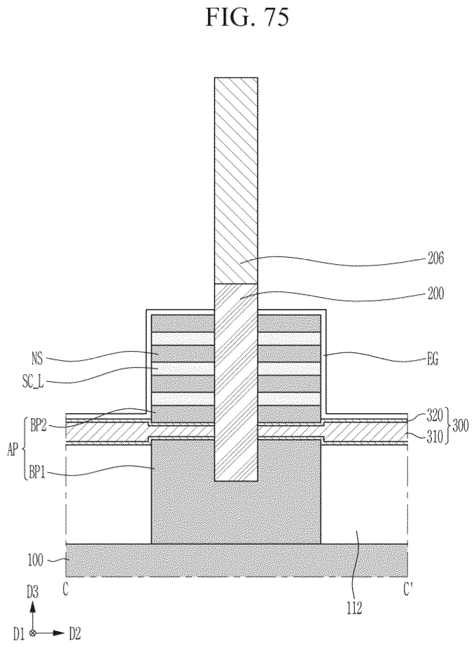

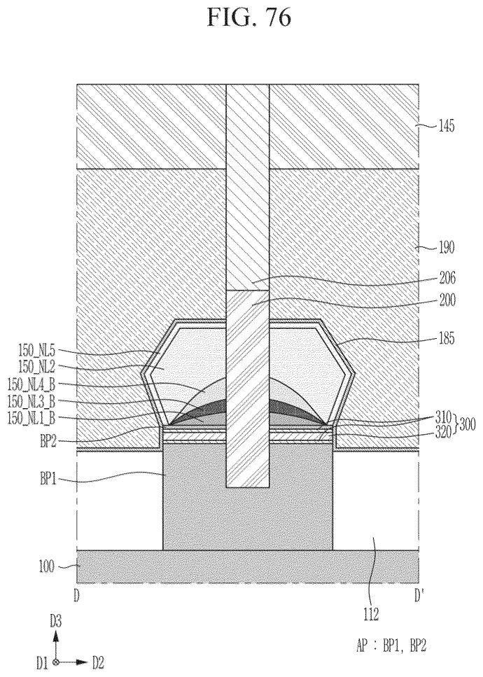

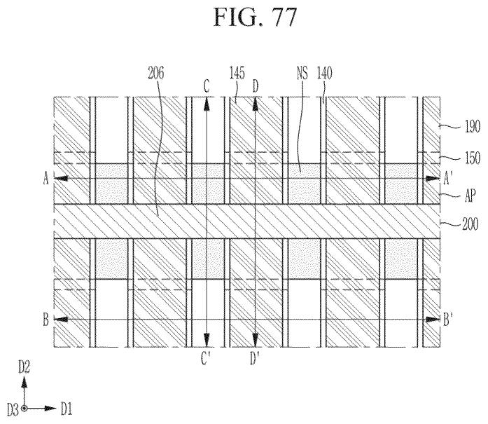

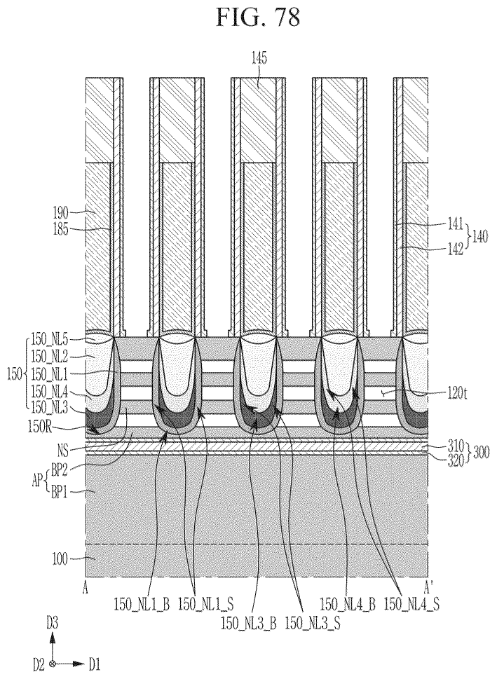

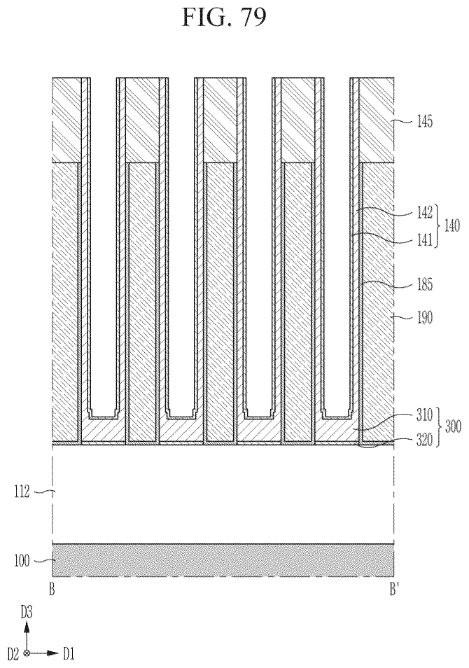

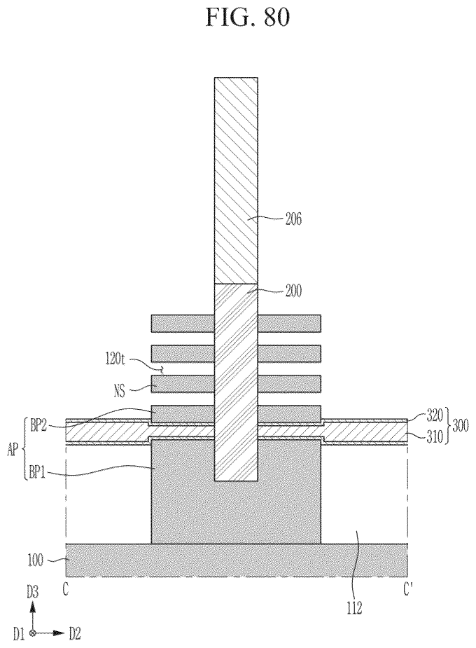

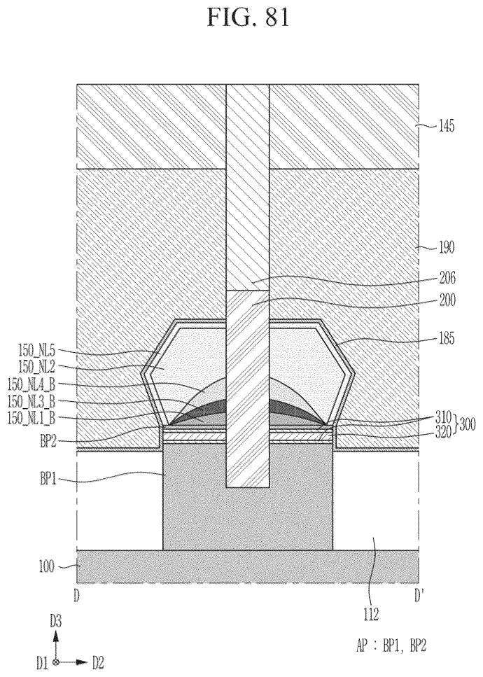

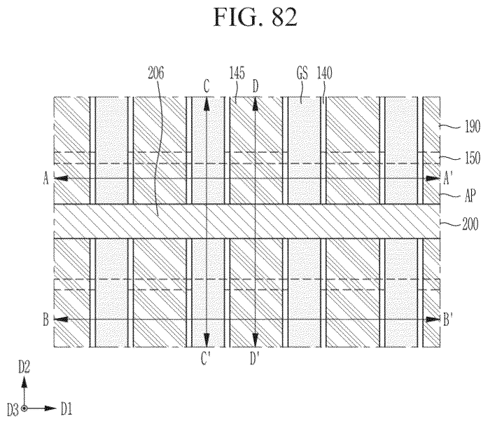

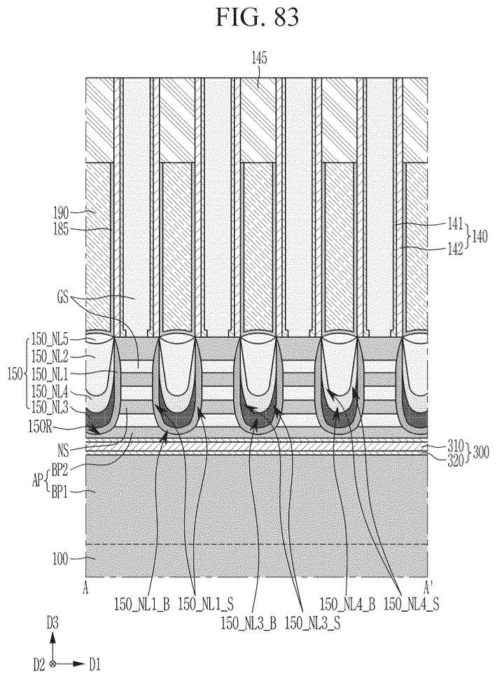

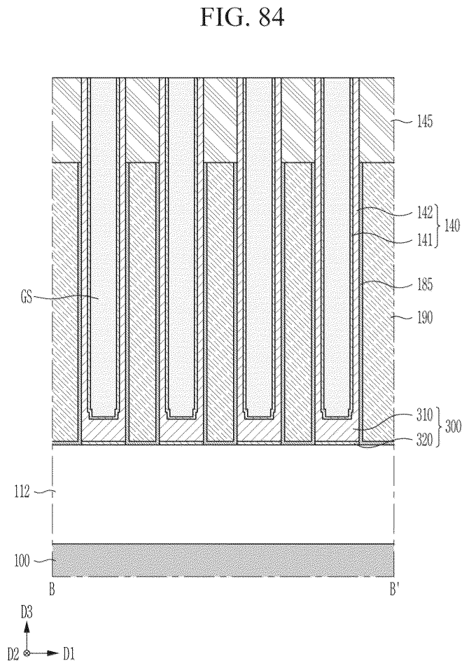

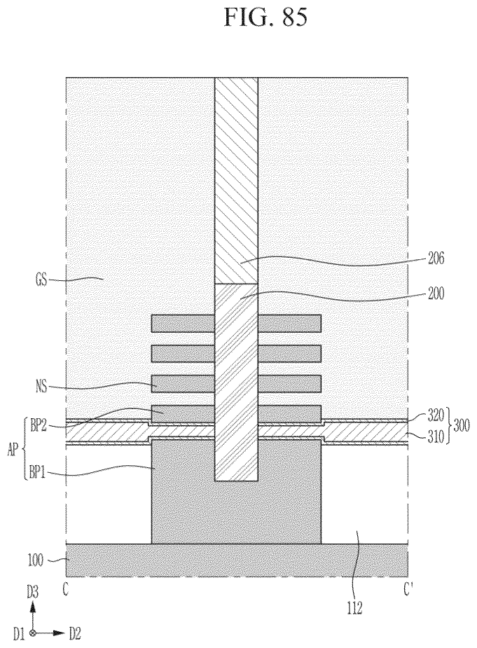

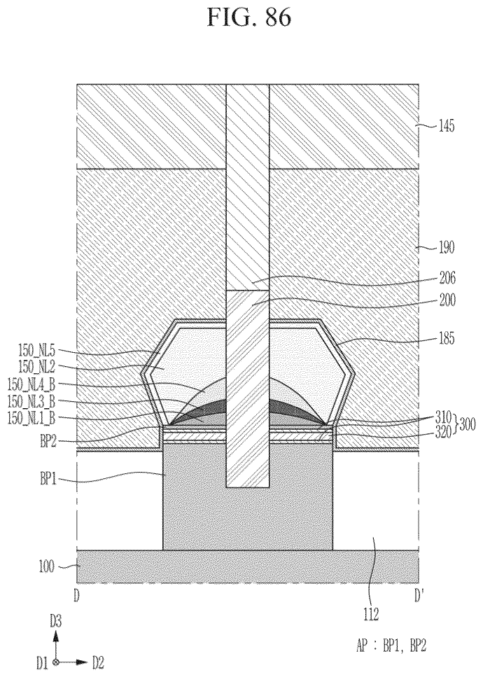

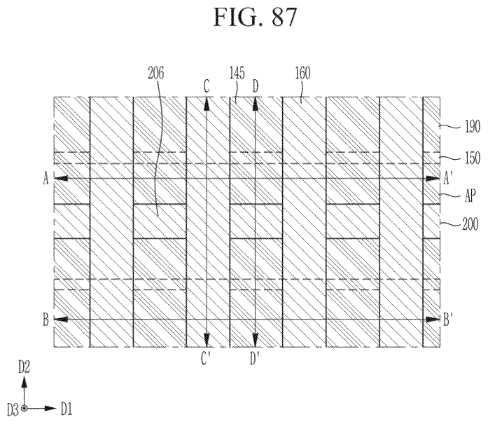

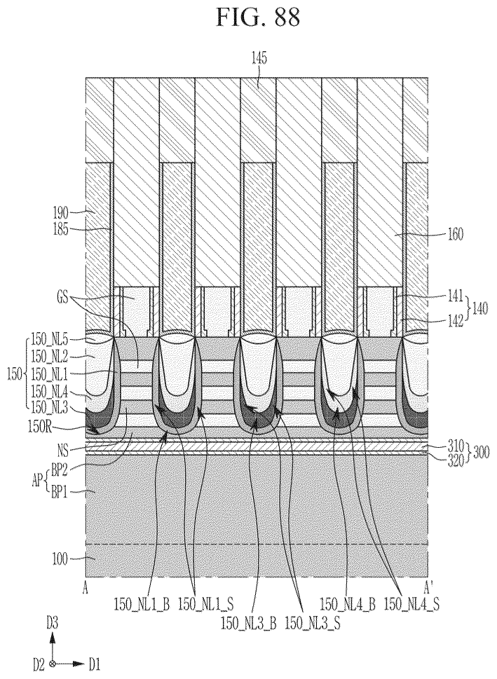

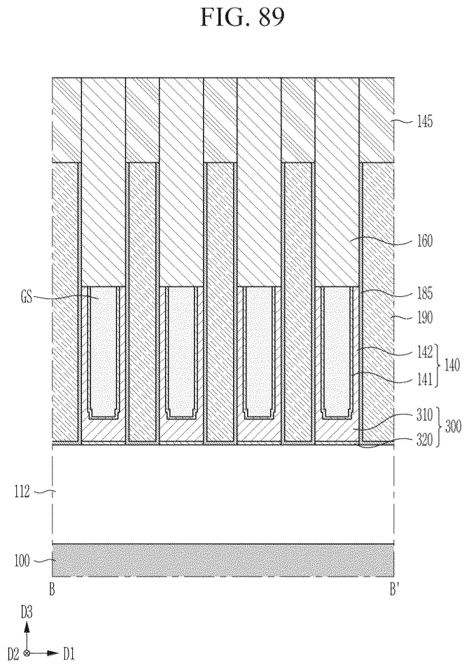

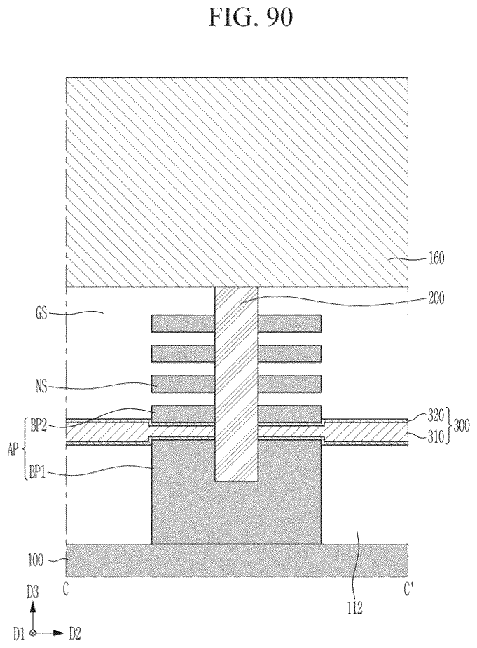

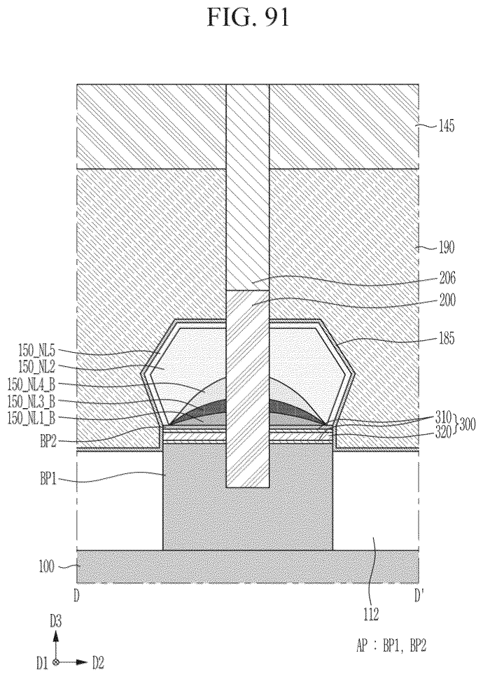

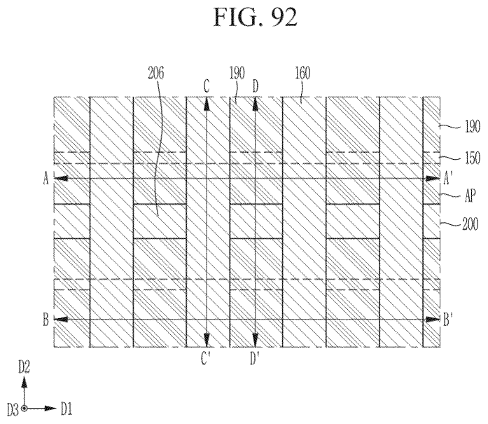

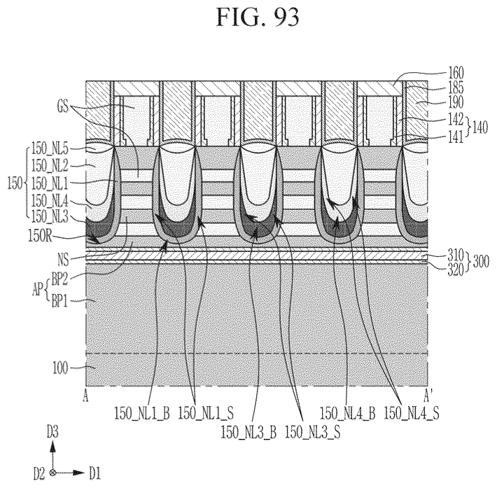

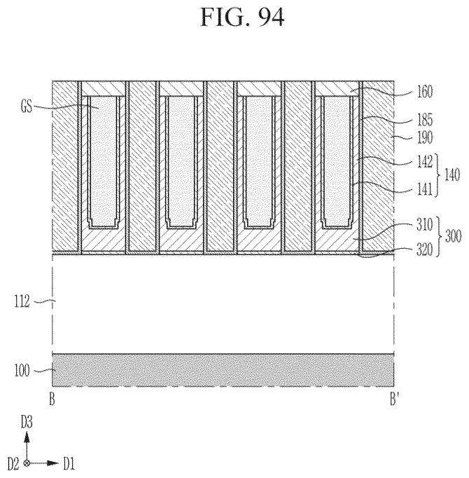

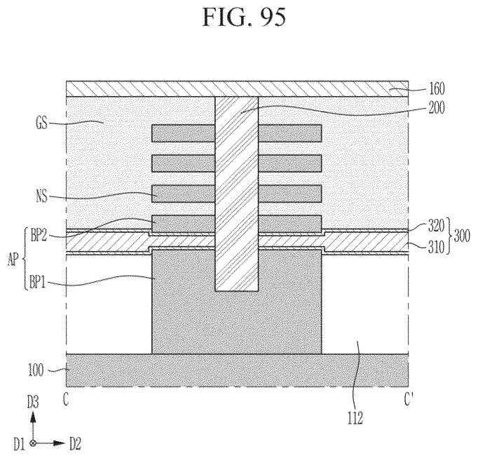

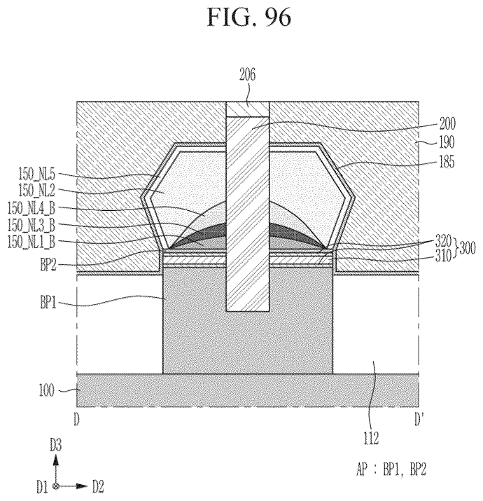

A method of manufacturing a semiconductor device according to an embodiment is described with reference to FIG. 17 to FIG. 96.

FIG. 17, FIG. 22, FIG. 27, FIG. 32, FIG. 37, FIG. 42, FIG. 47, FIG. 52, FIG. 57, FIG. 62, FIG. 67, FIG. 72, FIG. 77, FIG. 82, FIG. 87, and FIG. 92 are layout views showing intermediate steps of the method of manufacturing the semiconductor device.

FIG. 18, FIG. 23, FIG. 28, FIG. 33, FIG. 38, FIG. 43, FIG. 48, FIG. 53, FIG. 58, FIG. 63, FIG. 68, FIG. 73, FIG. 78, FIG. 83, FIG. 88, and FIG. 93 are cross-sectional views taken along a line A-A′ of FIG. 17, FIG. 22, FIG. 27, FIG. 32, FIG. 37, FIG. 42, FIG. 47, FIG. 52, FIG. 57, FIG. 62, FIG. 67, FIG. 72, FIG. 77, FIG. 82, FIG. 87, and FIG. 92, respectively.

FIG. 19, FIG. 24, FIG. 29, FIG. 34, FIG. 39, FIG. 44, FIG. 49, FIG. 54, FIG. 59, FIG. 64, FIG. 69, FIG. 74, FIG. 79, FIG. 84, FIG. 89, and FIG. 94 are cross-sectional views taken along a line B-B′ of FIG. 17, FIG. 22, FIG. 27, FIG. 32, FIG. 37, FIG. 42, FIG. 47, FIG. 52, FIG. 57, FIG. 62, FIG. 67, FIG. 72, FIG. 77, FIG. 82, FIG. 87, and FIG. 92, respectively.

FIG. 20, FIG. 25, FIG. 30, FIG. 35, FIG. 40, FIG. 45, FIG. 50, FIG. 55, FIG. 60, FIG. 65, FIG. 70, FIG. 75, FIG. 80, FIG. 85, FIG. 90, and FIG. 95 are cross-sectional views taken along a line C-C′ of FIG. 17, FIG. 22, FIG. 27, FIG. 32, FIG. 37, FIG. 42, FIG. 47, FIG. 52, FIG. 57, FIG. 62, FIG. 67, FIG. 72, FIG. 77, FIG. 82, FIG. 87, and FIG. 92, respectively.

FIG. 21, FIG. 26, FIG. 31, FIG. 36 FIG. 41, FIG. 46, FIG. 51, FIG. 56, FIG. 61, FIG. 66, FIG. 71, FIG. 76, FIG. 81, FIG. 86, FIG. 91, and FIG. 96 are cross-sectional views taken along a line D-D′ of FIG. 17, FIG. 22, FIG. 27, FIG. 32, FIG. 37, FIG. 42, FIG. 47, FIG. 52, FIG. 57, FIG. 62, FIG. 67, FIG. 72, FIG. 77, FIG. 82, FIG. 87, and FIG. 92.

As shown in FIG. 17 to FIG. 21, an active pattern AP, a sacrificial insulation layer SP, and a channel pattern structure U_AP are formed on a substrate 100. In an embodiment, the channel pattern structure U_AP includes a plurality of gate sacrificial pattern SC_L and a plurality of semiconductor pattern ACT_L that are alternately stacked (e.g., in the third direction D3).

In an embodiment, the substrate 100 may be a silicon-on-insulator (SOI) or a bulk silicon. Alternatively, the substrate 100 may be a silicon substrate, or other material, such as silicon germanium (SiGe), silicon germanium on insulator (SGOI), indium antimonide, lead tellurium compound, indium arsenic, indium phosphide, gallium arsenic, or gallium antimony. However, embodiments of the present disclosure are not necessarily limited thereto.

The active pattern AP protruded from the upper surface of the substrate 100 may be positioned on (e.g., disposed directly thereon) the substrate 100. The active pattern AP may protrude from the upper surface of the substrate 100 in the third direction D3.

In an embodiment, the active pattern AP may include a first lower pattern BP1 and a second lower pattern BP2. The first lower pattern BP1 may be positioned on (e.g., disposed directly thereon in the third direction D3) the substrate 100. The second lower pattern BP2 may be positioned on (e.g., disposed on) the first lower pattern BP1.

In an embodiment, the sacrificial insulation layer SP may be positioned between the first lower pattern BP1 and the second lower pattern BP2 (e.g., in the third direction D3). The sacrificial insulation layer SP may protrude from the upper surface of the first lower pattern BP1 in the third direction D3. The sacrificial insulation layer SP may be arranged to be spaced apart from each other along the second direction D2. The sacrificial insulation layer SP may extend longitudinally along the first direction D1.

In an embodiment, the sacrificial insulation layer SP may include a different material from the active pattern AP. The sacrificial insulation layer SP may include a material with an etch selectivity against the substrate 100. For example, in an embodiment the sacrificial insulation layer SP may include silicon germanium (SiGe). In an embodiment, the germanium (Ge) content included in the sacrificial insulation layer SP may be greater than the germanium (Ge) content included in substrate 100.

The channel pattern structure U_AP may be positioned on (e.g., disposed directly thereon in the third direction D3) the second lower pattern BP2. The channel pattern structure U_AP may be in direct contact with the second lower pattern BP2.

The plurality of gate sacrificial pattern SC_L and the plurality of semiconductor pattern ACT_L may be alternately stacked sequentially (e.g., in the third direction D3) to form the channel pattern structure U_AP. Among the plurality of gate sacrificial patterns SC_L, any gate sacrificial pattern may be positioned on the second lower pattern BP2 and in direct contact with the second lower pattern BP2. In FIG. 17 to FIG. 21, three gate sacrificial pattern SC_L and three semiconductor pattern ACT_L are shown alternately stacked. However, embodiments of the present disclosure are not necessarily limited thereto. For example, in some embodiments the number of stacks of the gate sacrificial pattern SC_L or the number of stacks of the semiconductor pattern ACT_L may be less than 3 or more than 3, respectively.

In an embodiment, the channel pattern structure U_AP may be formed using an epitaxial growth method. For example, by using an epitaxial growth method, a layer made of silicon germanium (SiGe) and a layer made of silicon (Si) may be formed alternately. In an embodiment, a mask structure is formed thereon. In an embodiment, the mask structure may be made of silicon nitride (SiN). The channel pattern structure U_AP may be formed by patterning the layer made of silicon germanium (SiGe) and the layer made of silicon by using the mask structure. In an embodiment, the plurality of gate sacrificial pattern SC_L may be made of silicon germanium (SiGe), and the plurality of semiconductor pattern ACT_L may be made of silicon (Si). However, embodiments of the present disclosure are not necessarily limited thereto, and the materials of the plurality of gate sacrificial pattern SC_L and the semiconductor pattern ACT_L may be changed in various ways.

On a plane, the plurality of channel pattern structure U_AP may extend longitudinally in the first direction D1. The plurality of channel pattern structures U_AP may be positioned on the substrate 100.

As shown in FIG. 22 to FIG. 26, a field insulation layer 112 is formed between the plurality of channel pattern structures U_AP (e.g., in the second direction D2).

A field insulation layer 112 is formed on (e.g., formed directly thereon) the substrate 100 on which the active pattern AP, the sacrificial insulation layer SP, and the channel pattern structure U_AP are formed. As an example, the field insulation layer 112 may include a field insulation layer 112 positioned on one surface of the active pattern AP and a field insulation layer 112 positioned on the other surface (e.g., a second surface) of the active pattern AP. In an embodiment, the field insulation layer 112 may entirely cover one surface of the active pattern AP. The field insulation layer 112 may cover a portion of the other surface (e.g., the second surface) of the active pattern AP.

In an embodiment, the thickness of the field insulation layer 112 in the third direction D3 may be greater than the thickness of the field insulation layer 112 in the third direction D3. In other words, the upper surface of the field insulation layer 112 may be positioned at a higher level than the upper surface of the field insulation layer 112. The upper surface of the field insulation layer 112 may be positioned farther from the upper surface of the substrate 100 than the upper surface of the field insulation layer 112. However, but it is not limited thereto, the thickness of the field insulation layer 112 in the third direction D3 may be substantially equivalent to the thickness of the field insulation layer 112 in the third direction D3.

In an embodiment, the field insulation layer 112 is an insulating material and may be made of a material that may fill an empty space. The field insulation layer 112 may include a material having an etch selectivity for a sacrificial insulation pattern 220, which will be described later. As an example, in an embodiment the field insulation layer 112 may include silicon nitride (SiN), silicon oxynitride (SiON), or a combination thereof. The field insulation layer 112 is shown as a single layer. However, embodiments of the present disclosure are not necessarily limited thereto.

Subsequently, the sacrificial insulation pattern 220 may be formed on (e.g., formed directly thereon in the third direction D3) the field insulation layer 112.

In an embodiment, the thickness of the sacrificial insulation pattern 220 along the third direction D3 may be greater than the thickness of the sacrificial insulation layer SP along the third direction D3. The lower surface of the sacrificial insulation pattern 220 may be positioned at a lower level (e.g., in the third direction D3) than the lower surface of sacrificial insulation layer SP. For example, the lower surface of the sacrificial insulation pattern 220 may be positioned closer to the upper surface of the substrate 100 than the lower surface of the sacrificial insulation layer SP (e.g., in the third direction D3). Additionally, the upper surface of the sacrificial insulation pattern 220 may be positioned at a higher level (e.g., in the third direction D3) than the upper surface of the sacrificial insulation layer SP. For example, the upper surface of the sacrificial insulation pattern 220 may be positioned farther from the upper surface of the substrate 100 than the upper surface of the sacrificial insulation layer SP (e.g., in the third direction D3). Accordingly, the side of the sacrificial insulation layer SP may completely overlap with the side of the sacrificial insulation pattern 220.

The sacrificial insulation pattern 220 may include a material having an etch selectivity for the field insulation layer 112. For example, in an embodiment the sacrificial insulation pattern 220 may include silicon oxide (SiO₂). The sacrificial insulation pattern 220 may include less dense silicon oxide (SiO₂) than the field insulation layer 112. However, embodiments of the present disclosure are not necessarily limited thereto. For example, in an embodiment in which the field insulation layer 112 and the sacrificial insulation pattern 220 each include silicon oxide (SiO₂), the field insulation layer 112 may include silicon oxide (SiO₂) that is denser and having greater solidity than the silicon oxide (SiO₂) included in the sacrificial insulation pattern 220. In an embodiment, the degree of the densification of the material included in the field insulation layer 112 may be determined according to an annealing temperature of silicon oxide (SiO₂), the number of annealing times, etc. during the process of forming the field insulation layer 112. For example, as the number of annealing increases, silicon oxide (SiO₂) may become denser.

As shown in FIG. 27 to FIG. 31, on the channel pattern structure U_AP, a spare gate insulating layer EG, a spare main gate electrode 120MP, and a spare capping layer 120_HM are formed (e.g., consecutively formed in the third direction D3). On a plane, the elongation direction of the spare main gate electrode 120MP and the spare capping layer 120_HM may intersect with the elongation direction of the channel pattern structure U_AP. In an embodiment, the spare main gate electrode 120MP and the spare capping layer 120_HM may extend longitudinally in the second direction D2 perpendicular to the first direction D1. The spare main gate electrode 120MP may be arranged to be spaced apart at a predetermined interval along the first direction D1.

As an example, in an embodiment the spare gate insulating layer EG may include silicon oxide (SiO₂). However, embodiments of the present disclosure are not necessarily limited thereto. The spare main gate electrode 120MP may include polysilicon. However, embodiments of the present disclosure are not necessarily limited thereto. The spare capping layer 120_HM may include, for example, silicon nitride (SiN). However, embodiments of the present disclosure are not necessarily limited thereto.

As shown in FIG. 32 to FIG. 36, the sacrificial insulation pattern 220 may be removed by performing an etching process. In an embodiment, the etching process may be done by a dry etching. However, embodiments of the present disclosure are not necessarily limited thereto. As described above, the sacrificial insulation pattern 220 may include a material having a etch selectivity against the field insulation layer 112. Therefore, even if the field insulation layer 112 is exposed as the sacrificial insulation pattern 220 is etched, the upper surface of the field insulation layer 112 may not be removed.

As the sacrificial insulation pattern 220 is removed, the first opened part OP1 may be formed. In an embodiment, the spare gate insulating layer EG, the field insulation layer 112, and the sacrificial insulation layer SP may be exposed by the first opened part OP1.

As shown in FIG. 37 to FIG. 41, in an embodiment the sacrificial insulation layer SP may be removed by performing an etching process. In an embodiment, the etching process may be done by a dry etching. However, embodiments of the present disclosure are not necessarily limited thereto. As described above, the sacrificial insulation layer SP may include a material having an etch selectivity against the active pattern AP. Therefore, even though the first lower pattern BP1 and the second lower pattern BP2 are exposed as the sacrificial insulation layer SP is etched, the upper surface of the first lower pattern BP1 and the lower surface of the second lower pattern BP2 may not be removed.

As the sacrificial insulation layer SP is removed, a recess 300R may be formed. The first lower pattern BP1 and the second lower pattern BP2 may be exposed by the recess 300R. As an example, the sides of the upper surface of the first lower pattern BP1 and the lower surface of the second lower pattern BP2 may be exposed by the recess 300R. At this time, as described above, the thickness along the third direction D3 of the sacrificial insulation pattern 220 may be thicker than the thickness along the third direction D3 of the sacrificial insulation layer SP. Therefore, the distance along the third direction D3 between the first lower pattern BP1 and the second lower pattern BP2 within the recess 300R may be less than the distance along the third direction D3 between the spare gate insulating layer EG and field insulation layer 112 within the recess 300R.

As shown in FIG. 42 to FIG. 46, a spare protection liner 320P and a spare protection insulation layer 310P may be formed sequentially within the recess 300R.

In an embodiment, the spare protection liner 320P may be first formed within the recess 300R. As an example, the spare protection liner 320P is conformally formed on (e.g., directly thereon) the upper surface of the field insulation layer 112, the upper surface of the first lower pattern BP1, the lower surface of the second lower pattern BP2, and the lower surface of the spare gate insulating layer EG, which are exposed by the recess 300R. Therefore, the spare protection liner 320P may be formed along the profile of the recess 300R. In an embodiment, the spare protection liner 320P may be formed on at least a portion of the side of the channel stacking structure U_AP and the upper surface of the channel stacking structure U_AP. In an embodiment, the spare protection liner 320P may be formed using an atomic layer deposition (ALD) process, a chemical vapor deposition (CVD) process, etc.

In addition, while forming the spare protection liner 320P, the first spare gate spacer 141P may be formed on both sides of the spare main gate electrode 120MP, both sides of the spare capping layer 120_HM, and the upper surface of the spare capping layer 120_HM. The first spare gate spacer 141P may be formed conformally along the profile of both sides of the spare main gate electrode 120MP, both sides of the spare capping layer 120_HM, and the upper surface of the spare capping layer 120_HM. The first spare gate spacer 141P may be integrally formed with the spare protection liner 320P. In an embodiment, the first spare gate spacer 141P may include the same material as the spare protection liner 320P.

Subsequently, the spare protection insulation layer 310P may be formed on (e.g., disposed directly thereon) the spare protection liner 320P. The spare protection insulation layer 310P may fill the recess 300R. The spare protection insulation layer 310P may be positioned between the spare gate insulating layer EG and the field insulation layer 112, and between the second lower pattern BP2 and the first lower pattern BP1. In an embodiment, the spare protection insulation layer 310P may be formed on the spare protection liner 320P formed on at least a portion of the side of the channel stacking structure U_AP and the upper surface of the channel stacking structure U_AP. In an embodiment, the spare protection insulation layer 310P may be formed using an atomic layer deposition (ALD) process, a chemical vapor deposition (CVD) process, etc.

Additionally, the second spare gate spacer 142P may be formed on (e.g., formed directly thereon) the first spare gate spacer 141P. In an embodiment, the second spare gate spacer 142P may include the same material as the spare protection insulation layer 310P.

As shown in FIG. 47 to FIG. 51, a source/drain pattern may be formed on the second lower pattern BP2.

In an embodiment, the etching process may first be carried out to sequentially etch at least a portion of the exposed spare protection insulation layer 310P and spare protection liner 320P. In an embodiment, the etching process may be a dry etching process. However, embodiments of the present disclosure are not necessarily limited thereto. As the etching process progresses, the portion of the spare protection insulation layer 310P positioned between the adjacent spare main gate electrodes 120MP may be removed. Additionally, as the etching process proceeds, the portion of the spare protection liner 320P positioned between the adjacent spare main gate electrodes 120MP may be removed.

Accordingly, the portion of the spare protection liner 320P and the portion of the spare protection insulation layer 310P that do not overlap with the spare main gate electrode 120MP in the third direction D3 may be removed. In an embodiment, the portion of the spare protection liner 320P and the portion of the spare protection insulation layer 310P that overlap with the spare main gate electrode 120MP in the third direction D3 may not be etched. Accordingly, the portion of the upper surface of the channel stacking structure U_AP may be exposed. Additionally, the portion of the upper surface of the field insulation layer 112 may be exposed.

At this time, the spare protection insulation layer 310P and the spare protection liner 320P positioned on at least a portion of the side of the channel stacking structure U_AP and the upper surface of the channel stacking structure U_AP may be removed together.

In an embodiment, using the spare main gate electrode 120MP and the spare gate spacer 140P as a mask, at least a portion of the channel pattern structure U_AP is etched to form the source/drain recess 150R.

As the source/drain recess 150R is formed, the active pattern ACT_L is separated and the channel pattern NS may be formed. The channel pattern NS may be positioned on both sides of the source/drain recess 150R. The channel pattern NS and the sacrificial pattern SC_L have an alternately stacked structure (e.g., in the third direction D3).

In an embodiment, a source/drain region 150 is then formed within the source/drain recess 150R.

In an embodiment, the source/drain region 150 may be formed using the epitaxial growth method. In this embodiment, interior walls of the source/drain recess 150R may be used as a seed. The interior walls of the source/drain recess 150R may include a side of the channel pattern NS, a side of the sacrificial pattern SC_L, and an upper surface of the active pattern AP.

As an example, the source/drain region 150 may be formed by sequentially forming the first epitaxial layer 150_NL1 and the second epitaxial layer 150_NL2. First, the first epitaxial layer 150_NL1 may be formed within the source/drain recess 150R, and then the second epitaxial layer 150_NL2 may be formed on the first epitaxial layer 150_NL1.

Accordingly, the first epitaxial layer 150_NL1 is formed to have a lower end 150_NL1_B positioned on the active pattern AP and a sidewall part 150_NL1_S extending from the lower end 150_NL1_B in the third direction D3. The second epitaxial layer 150_NL2 may fill the space of the source/drain recess 150R remaining after the first epitaxial layer 150_NL1 is formed. At this time, the second epitaxial layer 150_NL2 grows laterally in the second direction D2 during the epitaxial growth, so it may have a diamond shape with convex left and right sides (e.g., in the second direction D2).

In this way, by forming the source/drain region 150 before forming the barrier rib 200, defects caused by heterogeneous interfaces with the barrier rib 200 may be reduced when growing the epitaxial layer of the source/drain region 150.

Also, before forming the barrier rib 200, in view of the absence of the barrier rib 200, when the source/drain region 150 is formed, the first epitaxial layer 150_NL1 is formed to have a shape in which the lower end 150_NL1_B is convex upwardly in the third direction D3 in the first cross-section, for example, a bell shape. For example, the thickness T_NL1 of the lower end 150_NL1_B of the first epitaxial layer 150_NL1 is formed to have a shape in which the thickness increases from one end of the active pattern AP to the other in second direction D2, and after reaching the maximum value T_NL1_MAX at the midpoint in the second direction D2 of the active pattern AP, and the thickness decreases as it moves to the other end of the active pattern AP.

In an embodiment, a plurality of epitaxial layers may be further positioned between the first epitaxial layer 150_NL1 and the second epitaxial layer 150_NL2. As an example, in an embodiment shown in FIG. 47 to FIG. 51, a third epitaxial layer 150_NL3 and a fourth epitaxial layer 150_NL4 are further formed between the first epitaxial layer 150_NL1 and the second epitaxial layer 150_NL2.

Each of the third epitaxial layer 150_NL3 and the fourth epitaxial layer 150_NL4, like the first epitaxial layer 150_NL1, may be formed to have a lower end 150_NL3_B and 150_NL4_B, and a sidewall part 150_NL3_S and 150_NL4_S extending from the lower end 150_NL3_B and 150_NL4_B in the third direction D3. The lower end 150_NL3_B of the third epitaxial layer 150_NL3 may be positioned on (e.g., disposed directly thereon) the lower end 150_NL1_B of the first epitaxial layer 150_NL1, and the sidewall part 150_NL3_S may extend in the third direction D3 and be connected to (e.g., directly connected thereto) the sidewall part 150_NL1_S of the first epitaxial layer 150_NL1. The lower end 150_NL4_B of the fourth epitaxial layer 150_NL4 may be positioned on (e.g., disposed directly thereon) the lower end 150_NL3_B of the third epitaxial layer 150_NL3, and the sidewall part 150_NL4_S may extend in the third direction D3 and be connected to (e.g., directly connected thereto) the sidewall part 150_NL3_S of the third epitaxial layer 150_NL3.

Additionally, in an embodiment a fifth epitaxial layer 150_NL5 may be further formed on (e.g., disposed directly thereon) the second epitaxial layer 150_NL2. The fifth epitaxial layer 150_NL5 may cover the surface of the second epitaxial layer 150_NL2. The fifth epitaxial layer 150_NL5 may position the upper surface of the source/drain pattern at a higher level than the upper surface of the channel pattern NS.

As shown in FIG. 52 to FIG. 56, in an embodiment on the source/drain pattern, an etch stop layer 185, an interlayer insulating layer 190, and a capping layer 145 are sequentially formed.

In an embodiment, the etch stop layer 185 may be first formed conformally on the source/drain pattern.

In an embodiment, an interlayer insulating layer 190 may then be formed on the etch stop layer 185. The interlayer insulating layer 190 may be formed to fill the region between the spare main gate electrode 120MP. The interlayer insulating layer 190 is an insulating material and may be made of a material that may fill the empty space. For example, in an embodiment the interlayer insulating layer 190 may include silicon oxide, or tonen silazene (TOSZ), etc.

In an embodiment, the upper surface of the interlayer insulating layer 190 is then planarized using a chemical mechanical polishing (CMP) process. In addition, the upper region of the interlayer insulating layer 190 is removed to a predetermined thickness to form a groove.

In an embodiment, a capping layer 145 is then formed within the groove. The capping layer 145 may fill the region where the interlayer insulating layer 190 has been removed. The capping layer 145 may be positioned on (e.g., disposed directly thereon) the interlayer insulating layer 190. The upper surface of the interlayer insulating layer 190 may be covered by the capping layer 145. In an embodiment, the capping layer 145 may include silicon nitride. However, embodiments of the present disclosure are not necessarily limited thereto and the material of the capping layer 145 may vary.

In an embodiment, the thickness of the capping layer 145 may be selectively reduced using a chemical mechanical polishing (CMP) process.

As shown in FIG. 57 to FIG. 61, an etching process may be performed to form a second opened part OP2 that extends along the active pattern AP and penetrates the source/drain region 150. In an embodiment, the etching process may be performed by a dry or dry etching method. However, embodiments of the present disclosure are not necessarily limited thereto.

In the region where the channel pattern NS is positioned as shown in FIG. 60, the spare capping layer 120_HM, the spare main gate electrode 120MP, and the spare gate insulating layer EG may be etched to at least some depth of to form the second opened part OP2.

In the region where the source/drain region 150 is positioned as shown in FIG. 61, the capping layer 145, the interlayer insulating layer 190, and the etch stop layer 185, the source/drain region 150, the protection layer 300, and the active pattern may be etched to at least some depth of AP to form the second opened part OP2.

In an embodiment, the etching to form the second opened part OP2 may be done, for example, by forming a mask structure on the spare capping layer 120_HM and the capping layer 145 and using the mask structure as an etching mask.

As an example, the mask structure may extend longitudinally in the first direction D1 and may be formed in plurality to be spaced apart from each other along the second direction D2. In an embodiment, the mask structure may include, for example, oxide such as silicon oxide or an insulating nitride such as silicon nitride.

The second opened part OP2 may extend through the second lower pattern BP2 in the third direction D3 to the inside of the first lower pattern BP2.

In an embodiment, the second opened part OP2 extends longitudinally in the first direction D1 along the active pattern AP. The second opened part OP2 extends through the source/drain region 150 and the channel pattern NS in the third direction D3. Accordingly, the second opened part OP2 may separate the source/drain region 150 and the channel pattern NS into a plurality of parts.

As shown in FIG. 62 to FIG. 66, a spare barrier rib may be formed inside the second opened part OP2.

In an embodiment, the spare barrier rib may be formed by using at least one of, for example, a physical vapor deposition (PVD) process, a thermal chemical vapor deposition (thermal CVD) process, a low pressure chemical vapor deposition (LP-CVD) process, a plasma enhanced chemical vapor deposition (PE-CVD) process, or an atomic layer deposition (ALD) process. However, embodiments of the present disclosure are not necessarily limited thereto.

In an embodiment, the spare barrier rib may include, for example, silicon nitride (SiN), silicon carbon nitride (SiCN), silicon carbon oxide (SiOC), low dielectric constant material, or a combination thereof. However, embodiments of the present disclosure are not necessarily limited thereto.

In an embodiment, an etching process is then performed to remove a portion of the spare barrier rib, thereby forming a barrier rib 200. In an embodiment, the etching process may be performed by a dry or dry etching method. However, embodiments of the present disclosure are not necessarily limited thereto.

As an example, in an embodiment the spare barrier rib 200P may be etched so that the upper surface of the barrier rib 200 is positioned at a higher level (e.g., in the third direction D3) than the upper surface of the source/drain region 150. For example, the barrier rib 200 may penetrate the source/drain region 150 and protrudes above the source/drain region 150 in the third direction D3.

As such, in the semiconductor device according to some embodiments, the source/drain region 150 is formed and then the barrier rib 200 is formed. Accordingly, defects caused by heterogeneous interfaces with the barrier rib 200 may be reduced when growing the epitaxial layer of the source/drain region 150.

Also, before forming the barrier rib 200, due to the absence of the barrier rib 200, when the source/drain region 150 is formed, the first epitaxial layer 150_NL1 is formed to have a shape in which the lower end 150_NL1_B is convex upwardly in the third direction D3 in the first cross-section, for example, a bell shape. For example, the thickness T_NL1 of the lower end 150_NL1_B of the first epitaxial layer 150_NL1 is formed to have a shape in which the thickness increases from one end of the active pattern AP to the other in second direction D2, and after reaching the maximum value T_NL1_MAX at the midpoint in the second direction D2 of the active pattern AP, the thickness decreases as it moves to the other end of the active pattern AP.

Afterwards, by forming the barrier rib 200 and dividing the source/drain region 150 into, for example, the first part 150_A1 and the second part 150_A2, in the first part 150_A1 of the source/drain region 150, the thickness T_NL1 of the lower end 150_NL1_B of the first epitaxial layer 150_NL1 has a shape that increases as it approaches from the first points PT11 and PT21, which are positioned furthest from the barrier rib 200 in the second direction D2, towards the second points PT12 and PT22 that directly contact the barrier rib 200.

As shown in FIG. 67 to FIG. 71, in an embodiment a barrier rib capping layer 206 may be formed inside the second opened part OP2 remaining after the barrier rib 200 is formed.

In an embodiment, the barrier rib capping layer 206, for example, may be formed using at least one of a physical vapor deposition (PVD) process, a thermal chemical vapor deposition (a thermal CVD) process, a low pressure chemical vapor deposition (a LP-CVD) process, a plasma enhanced chemical vapor deposition (a PE-CVD) process, or an atomic layer deposition (ALD) process. However, embodiments of the present disclosure are not necessarily limited thereto.

The barrier rib capping layer 206 may be positioned on (e.g., disposed directly thereon in the third direction D3) the barrier rib 200. For example, the barrier rib capping layer 206 may overlap the barrier rib 200 in the third direction D3.

In an embodiment, the barrier rib capping layer 206, for example, may include silicon oxide (SiO), silicon nitride (SiN), silicon oxynitride (SiON), a low dielectric constant material, or a combination thereof.

As shown in FIG. 72 to FIG. 76, by removing a part of the capping layer 145 and the spare capping layer 120_HM, the upper surface of the spare main gate electrode 120MP is exposed, by removing the spare main gate electrode 120MP, the spare gate insulating layer EG is exposed.

As shown in FIG. 77 to FIG. 81, by removing the spare gate insulating layer EG, the channel pattern structure U_AP may be exposed between the gate spacer 140. In an embodiment, the plurality of gate sacrificial patterns SC_L positioned between the channel patterns NS may be removed to form a gate trench 120t between the channel patterns NS.

As shown in FIG. 82 to FIG. 86, a gate pattern GS may be formed within the gate trench 120t. In an embodiment, the gate pattern GS may be formed by embedding a conductive material and then performing a planarization process.

In an embodiment, the gate pattern GS may be formed using an atomic layer deposition (ALD) process, or chemical vapor deposition (CVD) process. In an embodiment, the gate pattern GS may include a doped polysilicon, a metal, a conductive metal nitride, a conductive metal carbide, or combinations thereof. However, embodiments of the present disclosure are not necessarily limited thereto, and the material of the gate pattern GS may vary.

As shown in FIG. 87 to FIG. 91, by using the capping layer 145 as a mask, at least a portion of the gate pattern GS is removed and a gate capping layer 160 is formed. In an embodiment, the gate capping layer 160 may include, for example, silicon nitride (SiN), silicon oxynitride (SiON), silicon (Si) carbide nitride (SiCN), silicon carbonate nitride (SiOCN), or a combination thereof.

As shown in FIG. 92 to FIG. 96, the interlayer insulating layer 190, the etch stop layer 185, and the gate capping layer 160 may be etched, thereby reducing the thickness. In an embodiment, an upper insulation layer 195 may then be formed on the interlayer insulating layer 190, the etch stop layer 185, and the gate capping layer 160, thereby forming the semiconductor device according to FIG. 12 to FIG. 16.

While this disclosure has been described in connection with non-limiting embodiments, it is to be understood that the disclosure is not limited to the described embodiments. On the contrary, the present disclosure includes various modifications and equivalent arrangements.

What is claimed is:

1. A semiconductor device comprising:
an active pattern extending in a first direction;
a source/drain pattern disposed on the active pattern, the source/drain pattern including source/drain regions spaced apart from each other in the first direction;
a channel pattern disposed between the source/drain regions;
a gate pattern extending in a second direction crossing the first direction, the gate pattern extending between the source/drain regions and surrounding at least a portion of the channel pattern; and
a barrier rib extending in the first direction, the barrier rib separating the source/drain region into a plurality of parts,
wherein a first part of the plurality of parts of the source/drain region includes a first epitaxial layer having a lower end disposed on the active pattern and a sidewall part extending from the lower end in a third direction crossing the first direction and the second direction, the sidewall part is connected to the channel pattern, and a second epitaxial layer disposed on the first epitaxial layer, the second epitaxial layer having a composition different from a composition of the first epitaxial layer,
in a cross-section cut from a center of the source/drain region in the first direction to the second and third directions, a lower end of the first epitaxial layer of the first part of the plurality of parts of the source/drain region has an asymmetric shape around an axis extending in the third direction.

2. The semiconductor device of claim 1, wherein:
in the cross-section cut from the center of the source/drain region in the first direction to the second direction and the third directions, the axis passes between a first point located on the upper surface of the active pattern and located furthest from the barrier rib in the second direction and a second point in direct contact with the barrier rib.

3. The semiconductor device of claim 1, wherein:
in the cross-section cut from the center of the source/drain region in the first direction to the second direction and the third direction, a second part of the plurality of parts of the source/drain region has a lower end having a symmetrical shape around the barrier rib with the lower end of the first epitaxial layer of the first part of the plurality of parts of the source/drain region.

4. The semiconductor device of claim 1, wherein:
the barrier rib extends in the third direction to penetrate the source/drain region.

5. The semiconductor device of claim 1, wherein:
the semiconductor device further includes an etch stop layer covering the source/drain region; and
the barrier rib extends in the third direction to penetrate the etch stop layer.

6. The semiconductor device of claim 1, wherein:
the semiconductor device further includes a barrier rib capping layer disposed directly on the barrier rib.

7. The semiconductor device of claim 1, wherein:
the barrier rib extends along the active pattern in the first direction, and divides the channel pattern into a plurality of parts.

8. The semiconductor device of claim 1, wherein:
in the cross-section cut from the center of the source/drain region in the first direction to the second direction and the third direction, in the first part of the plurality of parts of the source/drain region, a thickness of the lower end of the first epitaxial layer in the third direction has a minimum value at a first point positioned furthest from the barrier rib in the second direction, and a value greater than the minimum value at a second point in direct contact with the barrier rib.

9. The semiconductor device of claim 1, wherein:
in the cross-section cut from the center of the source/drain region in the first direction to the second direction and the third direction,
the lower end of the first epitaxial layer of the first part of the plurality of parts of the source/drain region is in planar contact with the barrier rib.

10. The semiconductor device of claim 1, wherein:
the first part of the plurality of parts of the source/drain region further includes a third epitaxial layer disposed between the first epitaxial layer and the second epitaxial layer, the third epitaxial layer having a lower end disposed on the lower end of the first epitaxial layer and a sidewall part extending from the lower end in the third direction and connected to the sidewall part of the first epitaxial layer, wherein the third epitaxial layer has a composition different from the compositions of the first epitaxial layer and the second epitaxial layer.

11. The semiconductor device of claim 10, wherein:
in the cross-section cut from the center of the source/drain region in the first direction to the second direction and the third direction;
a shape of the lower end of the third epitaxial layer of the first part of the plurality of parts of the source/drain region is asymmetric around the axis extending in the third direction;
a thickness of the lower end of the third epitaxial layer in the third direction has a minimum value at a first point positioned furthest from the barrier rib in the second direction and has a value greater than the minimum value at a second point in direct contact with the barrier rib; and
the lower end of the third epitaxial layer is in surface-contact with the barrier rib.

12. The semiconductor device of claim 1, wherein:
the semiconductor device further includes a protection layer disposed below the channel pattern and below the gate pattern.

13. The semiconductor device of claim 12, wherein the protection layer includes:
a protection insulation layer; and
a protection liner dispose above and below the protection insulation layer in the third direction.

14. A semiconductor device comprising:
an active pattern extending in a first direction;
a source/drain pattern disposed on the active pattern, the source/drain pattern including source/drain regions spaced apart from each other in the first direction;
a channel pattern disposed between the source/drain regions;
a gate pattern extending in a second direction crossing the first direction, the gate pattern extending between the source/drain regions and surrounding the channel pattern; and
a barrier rib extending in the first direction, the barrier rib separating the source/drain region into a plurality of parts,
wherein a first part of the plurality of parts of the source/drain region includes a first epitaxial layer having a lower end disposed on the active pattern and a sidewall part extending from the lower end in a third direction crossing the first direction and the second direction, the sidewall part is connected to the channel pattern, and a second epitaxial layer disposed on the first epitaxial layer, the second epitaxial layer having a composition different from a composition of the first epitaxial layer,
in a cross-section cut from a center of the source/drain region in the first direction to the second direction and the third direction, a thickness in the third direction of the lower end of the first epitaxial layer of the first part of the plurality of parts of the source/drain region has a minimum value at a first point positioned furthest from the barrier rib in the second direction, and a value greater than the minimum value at a second point in direct contact with the barrier rib.

15. The semiconductor device of claim 14, wherein:
the thickness in the third direction of the lower end of the first epitaxial layer of the first part of the plurality of parts of the source/drain region has a maximum value at the second point.

16. The semiconductor device of claim 14, wherein:
the thickness of the lower end of the first epitaxial layer in the third direction of the first part of the plurality of parts of the source/drain region increases as a distance to the second point decreases.

17. The semiconductor device of claim 14 second, wherein:
at the second point, a ratio of a thickness of the second epitaxial layer in the third direction to the thickness of the lower end of the first epitaxial layer in the third direction is greater than or equal to 2.

18. The semiconductor device of claim 14, wherein:
in the cross-section cut from the center of the source/drain region in the first direction to the second direction and the third direction, in the first part of the source/drain region, the lower end of the first epitaxial layer is in surface-contact with the barrier rib.

19. A semiconductor device comprising:
an active pattern extending in a first direction;
a source/drain pattern disposed on the active pattern, the source/drain pattern including source/drain regions spaced apart from each other in the first direction;
a channel pattern disposed between the source/drain regions;
a gate pattern extending in a second direction crossing the first direction, the gate pattern extending between the source/drain regions and surrounding the channel pattern; and
a barrier rib extending in the first direction, the barrier rib separating the source/drain region into a plurality of parts,
wherein a first part of the plurality of parts of the source/drain region includes a first epitaxial layer having a lower end disposed on the active pattern and a sidewall part extending from the lower end in a third direction crossing the first direction and the second direction, the sidewall part is connected to the channel pattern, and a second epitaxial layer disposed on the first epitaxial layer, the second epitaxial layer having a composition different from a composition of the first epitaxial layer,
in a cross-section cut from a center of the source/drain region in the first direction to the second and third directions, the lower end of the first epitaxial layer is in surface-contact with the barrier rib.

20. The semiconductor device of claim 19, wherein:
the sidewall part of the first epitaxial layer of the first part of the plurality of parts of the source/drain region is in surface-contact with the barrier rib.
